(19) United States
(12) Patent Application Publication
(10) Pub. No.: US 2024/0047328 A1
(43) Pub. Date: Feb. 8, 2024

(54) SEMICONDUCTOR PACKAGE WITH SUBSTRATE CAVITY

(71) Applicant: SAMSUNG ELECTRONICS CO., LTD., SUWON-SI (KR)

(72) Inventors: Jinduck Park, SUWON-SI (KR); Chansik Kwon, SUWON-SI (KR); Yongseong Kim, SUWON-SI (KR); Inwook Im, SUWON-SI (KR); Jiyeon Han, SUWON-SI (KR)

(21) Appl. No.: 18/341,345

(22) Filed: Jun. 26, 2023

(30) Foreign Application Priority Data
Aug. 2, 2022 (KR) 10-2022-0096273

(51) Int. Cl. H01L 23/498; H01L 25/065; H01L 23/31; H01L 23/00

(52) U.S. Cl. CPC H01L 23/49822; H01L 25/0657; H01L 23/3107; H01L 23/49838; H01L 24/32; H01L 24/48; H01L 24/73; H01L 2225/06506; H01L 2225/0651; H01L 2225/06548; H01L 2225/06562; H01L 2224/32145; H01L 2224/32225; H01L 2224/48145; H01L 2224/48227; H01L 2224/73265; H01L 2924/15153; H01L 2924/15184

(57) ABSTRACT

A semiconductor package includes a package base substrate including a substrate cavity formed therein, the substrate cavity extending from a top surface of the package base substrate downwardly toward a bottom surface of the package base substrate. The package base substrate further includes a plurality of base insulating layers, a plurality of substrate wiring patterns extending along at least one of a top surface and a bottom surface of each of the plurality of base insulating layers, and a plurality of substrate conductive vias which pass through at least one of the plurality of base insulating layers and are connected to the plurality of substrate wiring patterns. The semiconductor package further includes a plurality of semiconductor chips disposed at a bottom of the substrate cavity and stacked in a direction perpendicular to a plane of the package base substrate.

### CROSS-REFERENCE TO RELATED APPLICATION

This application is based on and claims priority under 35 U.S.C. § 119 to Korean Patent Application No. 10-2022-0096273, filed on Aug. 2, 2022, in the Korean Intellectual Property Office, the disclosure of which is incorporated by reference herein in its entirety.

### TECHNICAL FIELD

The present disclosure relates to a semiconductor package, and more particularly, to a semiconductor package with a substrate cavity.

### DISCUSSION OF THE RELATED ART

Recently, electronic devices have been developed to be more compact and multifunctional. Many of the electronic devices include semiconductor packages which include logical processors, memory systems, and other components that enable the various functionality of the electronic devices. To increase the compactness and portability of the devices, semiconductor packages have been developed with decreased thickness and increased integration. Additionally, multiple chips may be disposed within one semiconductor package.

In some cases, reducing the thicknesses of the various layers in the chips can cause cracks or other malfunctions during manufacture. There is a need in the art for semiconductor packages with increased space utilization and high reliability.

### SUMMARY

A semiconductor package includes a package base substrate including a substrate cavity formed therein, the substrate cavity extending from a top surface of the package base substrate downwardly toward a bottom surface of the package base substrate, the package base substrate further including a plurality of base insulating layers, a plurality of substrate wiring patterns extending along at least one of a top surface and a bottom surface of each of the plurality of base insulating layers, a plurality of substrate conductive vias which pass through at least one of the plurality of base insulating layers and are connected to the plurality of substrate wiring patterns, and a top solder resist layer which at least partially covers a top surface of an uppermost base insulating layer among the plurality of base insulating layers and bottom solder resist layer which at least partially covers a bottom surface of a lowermost base insulating layer among the plurality of base insulating layers. The semiconductor package further includes a plurality of semiconductor chips disposed at a bottom of the substrate cavity, wherein the plurality of semiconductor chips are stacked vertically and protrude upwards above a top surface of the package base substrate; and a plurality of bonding wires electrically connecting the plurality of semiconductor chips to the package base substrate, wherein a portion of one or more of the plurality of semiconductor chips extends beyond the substrate cavity in a horizontal direction.

A semiconductor package includes a package base substrate including a plurality of base insulating layers, a plurality of substrate wiring patterns extending along top and bottom surfaces of each the plurality of base insulating layers, a plurality of substrate conductive vias passing through at least one of the plurality of base insulating layers and connected to the plurality of substrate wiring patterns, a top solder resist layer at least partially covering a top surface of an uppermost base insulating layer among the plurality of base insulating layers, a bottom solder resist layer at least partially covering a bottom surface of a lowermost base insulating layer among the plurality of base insulating layers, and a substrate cavity formed within the plurality of base insulating layers and passing through the top solder resist layer. The semiconductor package additionally includes a plurality of semiconductor chips stacked on a bottom of the substrate cavity, wherein a lower portion of the plurality of semiconductor chips is disposed within the substrate cavity and wherein an upper portion of the plurality of semiconductor chips is disposed outside the substrate cavity; and a plurality of bonding wires for connecting the plurality of semiconductor chips to the package base substrate.

A semiconductor package includes a package base substrate including a plurality of base insulating layers, a plurality of substrate wiring patterns extending along at least one of a top surface and a bottom surface of each of the plurality of base insulating layers, a plurality of substrate conductive vias passing through at least one of the plurality of base insulating layers and connected to the plurality of substrate wiring patterns, a top solder resist layer at least partially covering a top surface of an uppermost base insulating layer among the plurality of base insulating layers, a bottom solder resist layer at least partially covering a bottom surface of a lowermost base insulating layer among the plurality of base insulating layers, and a substrate cavity formed within the top solder resist layer and extending downwardly from a top surface of the package base substrate toward an inside of the package base substrate; a plurality of semiconductor chips stacked vertically on a bottom of the substrate cavity, and protruding upwards over a top surface of the package base substrate; a plurality of bonding wires connecting the plurality of semiconductor chips to the package base substrate; and a mold layer covering the top surface of the package base substrate and filling the substrate cavity, wherein the mold layer covers the plurality of semiconductor chips and the plurality of bonding wires, wherein the substrate cavity is formed by a solder protrusion of the top solder resist layer, wherein a portion of the top solder resist layer including the solder protrusion has the greatest thickness within the top solder resist layer, and wherein a thickness of the thickest portion of the top solder resist layer is greater than a thickness of the thickest portion of the bottom solder resist layer.

### BRIEF DESCRIPTION OF THE DRAWINGS

Embodiments will be more clearly understood from the following detailed description taken in conjunction with the accompanying drawings. FIGS. 1 to 7E represent example embodiments as described herein.

FIGS. 1A and 1B are cross-sectional views of a semiconductor package according to embodiments.

FIGS. 2A and 2B are cross-sectional views of a semiconductor package according to embodiments.

FIG. 3 is a cross-sectional view of a semiconductor package according to an embodiment.

FIGS. 4A to 4D are cross-sectional views of a semiconductor package according to embodiments.

FIGS. 5A and 5B are cross-sectional views of a semiconductor package according to embodiments.

FIGS. 6A and 6B are cross-sectional views of a semiconductor package according to embodiments.

FIGS. 7A to 7E are cross-sectional views of a semiconductor package that illustrate a method of manufacturing the semiconductor package, according to embodiments.

### DETAILED DESCRIPTION OF THE EMBODIMENTS

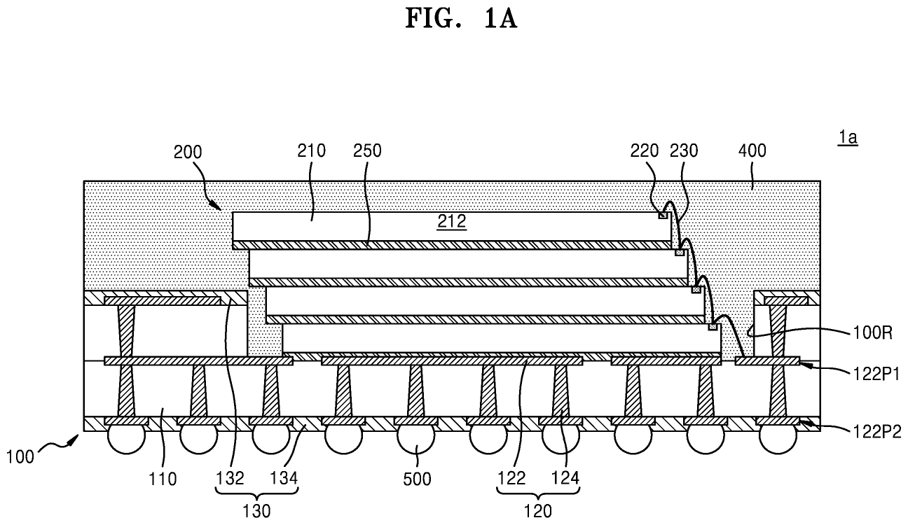

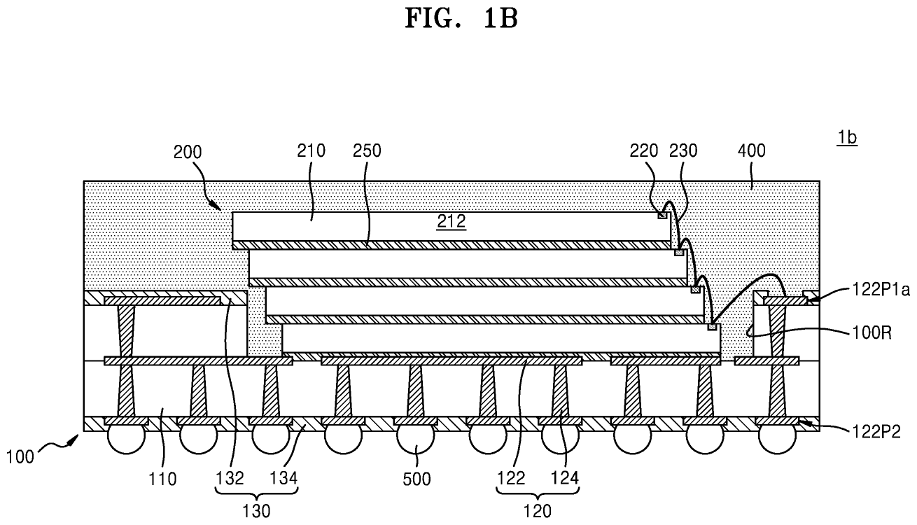

FIGS. 1A and 1B are cross-sectional views of a semiconductor package according to embodiments. Referring to FIG. 1A, a semiconductor package 1a may include a package base substrate 100 and a plurality of second semiconductor chips 200. The package base substrate 100 may include, for example, a printed circuit board (PCB), a ceramic substrate, a package-manufacturing wafer, or an interposer. In some embodiments, the package base substrate 100 may be a multilayered PCB.

The package base substrate 100 may include a base insulating layer 110 and a plurality of conductive patterns 120. The base insulating layer 110 may include a phenol resin, an epoxy resin, a polyimide, or a combination thereof. The base insulating layer 110 may include, for example, Frame Retardant 4 (FR-4), tetrafunctional epoxy, polyphenylene ether, epoxy/polyphenylene oxide, bismaleimide triazine (BT), Thermount, cyanate ester, polyimide, a liquid crystal polymer, or a combination thereof.

In some embodiments, the package base substrate 100 includes stacked base insulating layers 110. For example, the package base substrate 100 may include 2 stacked base insulating layers 110. As used herein, unless otherwise specified, the top surface of the base insulating layer 110 and the bottom surface of the base insulating layer 110 may refer to the top surface and the entire bottom surface of the base insulating layer 110 included in the package base substrate 100. For example, when the package base substrate 100 includes the plurality of stacked base insulating layers 110, the top surface of the base insulating layer 110 and the bottom surface of the base insulating layer 110 may refer to the top surface of the uppermost base insulating layer 110 and the bottom surface of the lowermost base insulating layer 110 among the plurality of base insulating layers 110. In some embodiments, when the package base substrate 100 includes a cavity in which one or more base insulating layers 110 are removed, the top surface of the base insulating layer 110 may refer to the top surface of the uppermost base insulating layer within the cavity. In some embodiments including the cavity, the top surface of the base insulating layer 110 may refer simultaneously to the top surface of the uppermost base insulating layer within the cavity and to the top surface of the uppermost base insulating layer outside of the cavity. In some embodiments, the top surface of the base insulating layer 110 refers only to the top surface of the uppermost base insulating layer 110, e.g., outside of the cavity.

The plurality of conductive patterns 120 may include a plurality of substrate wiring patterns 122 which extend along at least one of the top surface and the bottom surface of the base insulating layer 110, and a plurality of substrate conductive vias 124 which pass through the base insulating layer 110 and electrically connect substrate wiring patterns 122 that are located in different vertical levels. When the package base substrate 100 includes the plurality of stacked base insulating layers 110, the plurality of substrate wiring patterns 122 may extend along the top surface of the uppermost base insulating layer 110, the bottom surface of the lowermost base insulating layer 110, and between adjacent base insulating layers 110. Each of the plurality of substrate conductive vias 124 may pass through at least one base insulating layer 110 and electrically connect the substrate wiring patterns 122 located in different vertical levels. In some cases, the substrate wiring patterns 122 located in different vertical levels may be described as being located on different wiring layers.

The plurality of wiring patterns 122 may include electrolytically deposited (ED) copper foil, rolled-annealed (RA) copper foil, stainless steel foil, aluminum foil, ultra-thin copper foil, sputtered copper, copper alloy, or combinations thereof. For example, each of the plurality of substrate wiring patterns 122 may have a thickness of several m. A plurality of substrate conductive vias 124 may include copper, nickel, stainless steel, or beryllium copper.

A wiring layer refers to an electrically conductive pattern that extends on a plane. The package base substrate 100 may have a wiring layer disposed on the top surface and on the bottom surface of the base insulating layer 110. When the package base substrate 100 includes a plurality of stacked base insulating layers 110, the package base substrate 100 may have a wiring layer disposed on the top surface and on the bottom surface of each of the plurality of base insulating layers 110, that is, disposed on the top surface of the uppermost base insulating layer 110 and on the bottom surface of the lowermost base insulating layer 110, and a wiring layer further disposed between two adjacent base insulating layers 110. For example, the package base substrate 100 may have a number of wiring layers that is equal to the number of stacked number of included base insulating layers 110, plus one.

Some substrate wiring patterns 122 that are adjacent to the bottom surface of the package base substrate 100 may be referred to as a plurality of lower connection pads 122P2, and some substrate wiring patterns 122 that are adjacent to the top surface of the package base substrate 100 may be referred to as a plurality of upper connection pads 122P1. For example, the plurality of upper connection pads 122P1 may comprise substrate wiring patterns 122 that are disposed on the top surface of the base insulating layer 110, or some substrate wiring patterns 122 that are disposed on the bottom surface of the base insulating layer 110. In some embodiments, the plurality of upper connection pads 122P1 may comprise wiring patterns 122 that are disposed on the top surface of a base insulating layer 110 that is directly below the uppermost base insulating layer 110. Substrate wiring patterns 122 that are disposed between two adjacent base insulating layers 110 may be collectively referred to as an internal wiring pattern.

The package base substrate 100 may further include a solder resist layer 130 disposed on the top surface and the bottom surface of the base insulating layer 110. For example, when the package base substrate 100 includes a plurality of stacked base insulating layers 110, the solder resist layer 130 may be arranged on the top surface of the uppermost base insulating layer 110 and on the bottom surface of the lowermost base insulating layer 110. The solder resist layer 130 may include a top solder resist layer 132 which covers the top surface of the uppermost base insulating layer 110, and a bottom solder resist layer 134 which covers the bottom surface of the lowermost base insulating layer 110. In some embodiments, the bottom solder resist layer 134 exposes the plurality of lower connection pads 122P2. For example, in some embodiments, the plurality of lower connection pads 122P2 are formed in openings of the bottom solder resist layer 134 to enable external connections.

In some embodiments, when the plurality of upper connection pads 122P1 are arranged on the top surface of a base insulating layer 110 that is directly below the uppermost base insulating layer 110, the top solder resist layer 132 completely covers the top surface of the uppermost base insulating layer 110. In some embodiments, the top solder resist layer 132 partially covers the top surface of the uppermost base insulating layer 110. For example, the top solder resist layer 132 may cover portions of the top surface of the uppermost base insulating layer 110 that are not disposed within a substrate cavity 100R of the package base substrate 100. The thickness of each of the top solder resist layer 132 and the bottom solder resist layer 134 may be about 10 μm to about 20 μm.

In some embodiments, each of the top solder resist layer 132 and the bottom solder resist layer 134 may be formed by applying solder mask insulating ink to the top and bottom surfaces of the base insulating layer 110 by using screen printing or inkjet printing, and then hardening the solder mask insulating ink using ultraviolet (UV) or infrared (IR) light.

In some embodiments, each of the top solder resist layer 132 and the bottom solder resist layer 134 may be formed by applying photo-imageable solder resist to the top and bottom surfaces of the base insulating layer 110 by using screen printing or spray coating, or by sticking a film-type solder resist material to the top and bottom surfaces of the base insulating layer 110 by using a laminating method, and then removing an unnecessary portion through exposure and development, and then performing hardening using heat, UV light, or IR light.

The package base substrate 100 may have a substrate cavity 100R, which extends from the top surface of the package base substrate 100 downwardly toward the inside of the package base substrate 100. For example, the substrate cavity 100R may be formed within a portion of, or one or more of the base insulating layers 110. The substrate cavity 100R may pass through the top solder resist layer 132 and extend toward the inside of the package base substrate 100. In some embodiments, when the package base substrate 100 includes a plurality of stacked base insulating layers 110, the substrate cavity 100R may pass through the top solder resist layer 132 and pass through at least one base insulating layer 110 at an upper side among the stacked base insulating layers 110, and expose substrate wiring patterns 122 at the bottom of the substrate cavity 100R. At least some of the substrate wiring patterns 122 exposed at the bottom of the substrate cavity 100R may be a plurality of upper connection pads 122P1. In at least one embodiment, the substrate cavity 100R through the top solder resist layer 132 and through only a portion of one base insulating layer 110.

The depth of the substrate cavity 100R from the top surface of the package base substrate 100 to the bottom of the substrate cavity 100R may be greater than 10 μm and less than the thickness of the package base substrate 100. In some embodiments, the depth of the substrate cavity 100R may be about 20 μm to about 50 μm.

A plurality of external connection terminals 500 may be respectively attached to a plurality of lower connection pads 122P2. The plurality of external connection terminals 500 may be solder balls or bumps. The external connection terminals 500 may electrically connect the semiconductor package 1a to an external electronic device. Since the plurality of external connection terminals 500 are respectively attached to the plurality of lower connection pads 122P2, the lower connection pads 122P2 may be referred to as a ball land. In some embodiments, the plurality of external connection terminals 500 extend into the bottom solder resist layer 134. For example, in some embodiments, the bottom solder resist layer 134 may include a plurality of recessions to expose the plurality of lower connection pads 122P2 on which the plurality of external connection terminals 500 are disposed.

A plurality of semiconductor chips 200 may be sequentially stacked on the package base substrate 100 in a vertical direction. For example, the plurality of stacked semiconductor chips 200 may be sequentially stacked in a vertical direction from the bottom of the substrate cavity 100R of the package base substrate 100. In some embodiments, the plurality of semiconductor chips 200 are shifted with substantially regular spacing and are stacked in a step shape. A portion of each of the remaining semiconductor chips 200 stacked on the lowermost semiconductor chip 200 among the plurality of semiconductor chips 200 may overhang another semiconductor chip at the lower side. In embodiments, edge portions of upper semiconductor chips stacked on the lowermost semiconductor chip 200 may extend beyond the substrate cavity 100R in a horizontal direction parallel to the package base substrate 100.

Although FIG. 1 illustrates an example semiconductor package 1a that includes four stacked semiconductor chips 200, embodiments are not necessarily limited thereto. For example, the semiconductor package 1a may include 5 or more stacked semiconductor chips 200. In some embodiments, the semiconductor package 1a may include a multiple of 4 stacked semiconductor chips 200. For example, each of a plurality of stacked semiconductor chips 200 may have a thickness of about 20 μm to about 50 μm.

Each of the semiconductor chips 200 may include a semiconductor substrate 210. The semiconductor substrate 210 may include silicon (Si). Alternatively, the semiconductor substrate 210 may include a semiconductor element, such as germanium (Ge), or a compound semiconductor, such as silicon carbide (SiC), gallium arsenide (GaAs), indium arsenide (InAs), and indium phosphide (InP). Some embodiments of the semiconductor substrate 210 may have a silicon-on-insulator (SOI) structure. For example, the semiconductor substrate 210 may include a buried oxide (BOX) layer. The semiconductor substrate 210 may include a conductive region such as a doped well. The semiconductor substrate 210 may include various isolation structures including a shallow trench isolation (STI) structure. The semiconductor substrate 210 may include an active surface and an inactive surface opposite to the active surface.

The semiconductor chips 200 include various kinds of individual devices and may each include a semiconductor device 212 formed on the active surface of the semiconductor substrate 210. The plurality of individual devices may include various microelectronic devices, for example, a metal-oxide-semiconductor field effect transistor (MOSFET) (e.g., a complementary metal-insulator-semiconductor (CMOS) transistor), a system large-scale integration (LSI), an image sensor (e.g., a CMOS imaging sensor (CIS)), a micro-electro-mechanical system (MEMS), an active device, and a passive device. The plurality of individual devices may be electrically connected to the conductive region of the semiconductor substrate 210. The semiconductor device 212 may further include a conductive wiring or a conductive plug configured to electrically connect at least two of the plurality of individual devices to each other or to electrically connect the plurality of individual devices to the conductive region of the semiconductor substrate 210. In addition, each of the plurality of individual devices may be electrically isolated from other individual devices adjacent thereto by an insulating film.

In some embodiments, each of the plurality of semiconductor chips 200 may be a semiconductor memory chip. The semiconductor memory chip may include volatile memory, such as flash memory, phase-change random access memory (PRAM), magneto-resistive RAM (MRAM), ferroelectric RAM (FeRAM), or resistive RAM (RRAM). The flash memory may be a V-NAND flash memory. The semiconductor memory chip may be a volatile semiconductor memory chip, such as dynamic random access memory (DRAM) or static RAM (SRAM). In some embodiments, at least one of the plurality of semiconductor chips 200 may be a semiconductor logic chip. For example, the semiconductor logic chip may be or include a central processing unit (CPU) chip, a graphics processing unit (GPU) chip, or an application processor (AP) chip.

Each of the plurality of semiconductor chips 200 may include a plurality of chip pads 220 arranged on the active surface of each of the plurality of semiconductor chips 200. Each of the plurality of semiconductor chips 200 may be stacked on the package base substrate 100 such that the active surface of each of the plurality of semiconductor chips 200 faces upwards. For example, each of the plurality of semiconductor chips 200 may be stacked such that their active surfaces are disposed distal to the package base substrate 100, and such that the inactive surface of each of the plurality of semiconductor chips 200 is disposed proximate to the package base substrate 100. The plurality of semiconductor chips 200 may be electrically connected to the package base substrate 100 through a plurality of bonding wires 230.

In some embodiments, the plurality of bonding wires 230 may be sequentially connected from the chip pads 220 of the uppermost semiconductor chip 200 to the chip pads 220 of the lowermost semiconductor chip 200, and may then be connected to the plurality of upper connection pads 122P1. In some embodiments, the plurality of bonding wires 230 may be respectively connected to the plurality of chip pads 220 of each of the plurality of semiconductor chips 200, and to the plurality of upper connection pads 122P1.

The plurality of semiconductor chips 200 may include a die adhesive film 250 attached to the lower surface of each of the semiconductor chips 200, and between adjacent semiconductor chips of the plurality of semiconductor chips 200. The die adhesive film 250 may also be attached to the lower structure, such as the bottom of the substrate cavity 100R.

The die adhesive film 250 may include an inorganic adhesive or a polymer adhesive. For example, the polymer adhesive may include a thermosetting polymer or a thermoplastic polymer. The thermosetting polymer develops a three-dimensional cross-link structure after its monomers are heated, and is not softened when reheated. In contrast, the thermoplastic polymer exhibits plasticity when heated and has a linear polymer structure. The polymer adhesive may include a hybrid type produced by mixing these two types of polymers. Embodiments of the die adhesive film 250 have a thickness of about 5 μm to about 15 μm.

In some embodiments, the semiconductor package 1a further includes a controller chip disposed on the package base substrate 100 or within the uppermost semiconductor chip 200 among the plurality of semiconductor chips 200. A controller may be embedded in the controller chip. The controller may control access to data stored in the plurality of semiconductor chips 200. For example, the controller may control the write/read operation of a plurality of semiconductor chips 200, such as flash memory, according to the control command of an external host. In some embodiments, the controller may include a separate control semiconductor chip, such as an application specific integrated circuit (ASIC). The controller may perform wear leveling, garbage collection, bad block management and error correcting code (ECC) on a nonvolatile semiconductor memory chip.

One or more of the plurality of semiconductor chips 200 may be located within the substrate cavity 100R. An upper portion of the plurality of semiconductor chips 200 may protrude upwards over the top surface of the package base substrate 100. A lower portion of the plurality of stacked semiconductor chips 200 may be positioned within the substrate cavity 100R. For example, the lower portion of the plurality of stacked semiconductor chips 200 may be positioned within the substrate cavity 100R, and the upper portion thereof may be positioned outside the substrate cavity 100R. For example, the upper portion of the plurality of stacked semiconductor chips 200 may be disposed at a vertical level higher than that of the top surface of the package base substrate 100, that is, the top surface of the top solder resist layer 132. The lower portion of the plurality of stacked semiconductor chips 200 may be disposed at a vertical level lower than that of the top surface of the package base substrate 100, that is, the top surface of the top solder resist layer 132.

In some embodiments, a part of the upper portion of the plurality of stacked semiconductor chips 200 might not overlap with the substrate cavity 100R in the vertical direction. For example, a portion of the upper portion of the plurality of stacked semiconductor chips 200 may overhang the substrate cavity 100R in the horizontal direction. For example, a portion of the uppermost semiconductor chip 200 may be shifted with respect to the lowermost semiconductor chip 200 in the horizontal direction, or a portion of the upper semiconductor chips 200 may be positioned outside of a planar area of the substrate cavity 100R as apparent in a plan view.

Although FIG. 1A illustrates an example in which the entirety of the lowermost semiconductor chip 200 and the lower portion of the second lowest semiconductor chip 200 is positioned within the substrate cavity 100R, embodiments are not necessarily limited thereto. In some embodiments, only the lower portion of the lowermost semiconductor chip 200 is positioned within the substrate cavity 100R. In some embodiments, the entirety of the lowermost semiconductor chip 200 may be positioned within the substrate cavity 100R, or two or more semiconductor chips on a lower side of the plurality of semiconductor chips 200 may be positioned within the substrate cavity 100R.

Although FIG. 1A illustrates an example in which the entirety of two upper side semiconductor chips 200 is positioned outside of the substrate cavity 100R, and the upper portion of one semiconductor chip 200 below the two semiconductor chips 200 is positioned outside of the substrate cavity 100R, embodiments are not necessarily limited thereto. In some embodiments, only the upper portion of the uppermost semiconductor chip 200 is positioned outside of the substrate cavity 100R. In some embodiments, only the uppermost semiconductor chip 200, or the uppermost semiconductor chip 200 and a portion of the second highest semiconductor chip 200, or two upper side semiconductor chips 200 may be positioned outside the substrate cavity 100R.

The plurality of semiconductor chips 200 may be sequentially stacked in a vertical direction on the bottom of the substrate cavity 100R of the package base substrate 100. For example, the lowermost semiconductor chip 200 may be attached to the bottom of the substrate cavity 100R of the package base substrate 100 with the die adhesive film 250, and the remaining semiconductor chips 200 may be attached to the lower semiconductor chip 200 with the die adhesive film 250. The plurality of semiconductor chips 200 may be sequentially stacked on the bottom of the substrate cavity 100R in a vertical direction and be spaced apart from the inner sidewall of the substrate cavity 100R of the package base substrate 100.

The die adhesive film 250, which covers the bottom surface of the lowermost semiconductor chip 200, may cover the base insulating layer 110 and the substrate wiring pattern 122. For example, the die adhesive film 250, which covers the bottom surface of the lowermost semiconductor chip 200, may cover exposed portions of the base insulating layer 110 and exposed portions of the substrate wiring pattern 200 at the bottom of the substrate cavity 100R.

In some embodiments, the plurality of upper connection pads 122P1 may be arranged on the top surface of the base insulating layer 110 that is positioned on the bottom of the substrate cavity 100R, e.g., the top surface of a base insulating layer below the uppermost base insulating layer 110. A plurality of bonding wires 230 may be attached between the plurality of chip pads 220 and the plurality of upper connection pads 122P1a. Some of the plurality of bonding wires 230 may be located in the substrate cavity 100R, and remaining bonding wires 230 may be located outside the substrate cavity 100R. The plurality of semiconductor chips 200 may be electrically connected to the package base substrate 100 through a plurality of bonding wires 230.

A mold layer 400 covers the top surface of the package base substrate 100. The mold layer 400 may fill the substrate cavity 100R and cover the plurality of semiconductor chips 200 and the plurality of bonding wires 230, and may be arranged on the package base substrate 100. The molding layer 240 may include an epoxy mold compound (EMC).

Since the lower portion of the plurality of stacked semiconductor chips 200 of the semiconductor package 1a is positioned within the substrate cavity 100R of the package base substrate 100, the thickness of the semiconductor package 1a may decrease, and the semiconductor package 1a may have decreased size and increased space utilization.

Since only a part of the upper portion of the plurality of stacked semiconductor chips 200 of the semiconductor package 1a is positioned outside the substrate cavity 100R of the package base substrate 100, the structural reliability of the semiconductor package 1a may be increased, as compared to a comparative semiconductor package in which all of the plurality of semiconductor chips 200 are positioned on the top surface of the package base substrate 100.

Since only a part of the upper portion of the plurality of stacked semiconductor chips 200 of the semiconductor package 1a is positioned outside the substrate cavity 100R of the package base substrate 100, the thickness of the semiconductor package 1a may not increase even when the thickness of each of the plurality of semiconductor chips 200 is increased. Accordingly, a plurality of relatively thick semiconductor chips 200 may be stacked within the semiconductor package 1a while maintaining structural reliability and increasing integration.

Because the plurality of semiconductor chips 200 are respectively attached to the substrate wiring patterns 122 exposed at the bottom of the substrate cavity 100R in the semiconductor package 1a, heat generated from the plurality of semiconductor chips 200 may be easily discharged to the outside through the plurality of substrate wiring patterns 122.

Referring to FIG. 1B, a semiconductor package 1a may include a package base substrate 100 and a plurality of second semiconductor chips 200.

The package base substrate 100 may include a base insulating layer 110 and a plurality of conductive patterns 120. The package base substrate 100 may have a substrate cavity 100R which extends from the top surface of the package base substrate 100 toward the bottom of the package base substrate 100. The plurality of stacked semiconductor chips 200 may be sequentially stacked in a vertical direction from the bottom of the substrate cavity 100R of the package base substrate 100.

The plurality of conductive patterns 120 may include a plurality of substrate wiring patterns 122 and a plurality of substrate conductive vias 124. Some substrate wiring patterns 122 that are adjacent to the bottom surface of the package base substrate 100 may be referred to as a plurality of lower connection pads 122P2, and some substrate wiring patterns 122 that are adjacent to the top surface of the package base substrate 100 may be referred to as a plurality of upper connection pads 122P1a. In some embodiments, the plurality of upper connection pads 122P1a may disposed on the top surface of the uppermost base insulating layer 110. The top solder resist layer 132 may cover the top surface of the uppermost base insulating layer 110 and expose the plurality of upper connection pads 122P1a.

A plurality of bonding wires 230 may be attached to the plurality of chip pads 220 and the plurality of upper connection pads 122P1a. For example, one end of each of the bonding wires 230 may be connected to each of the plurality of chip pads 220 of the lowermost semiconductor chip 200, and the other end of each of the bonding wires 230 may be connected to each of the plurality of upper connection pads 122P1a. In some embodiments, when the entirety of the lowermost semiconductor chip 200 is positioned in the substrate cavity 100R, the plurality of upper connection pads 122P1a may be disposed at a vertical level higher than that of the plurality of chip pads 220 of the lowermost semiconductor chip 200. In some embodiments, when only the lower portion of the lowermost semiconductor chip 200 is positioned in the substrate cavity 100R, the plurality of upper connection pads 122P1a may be disposed at a vertical level lower than that of the plurality of chip pads 220 of the lowermost semiconductor chip 200.

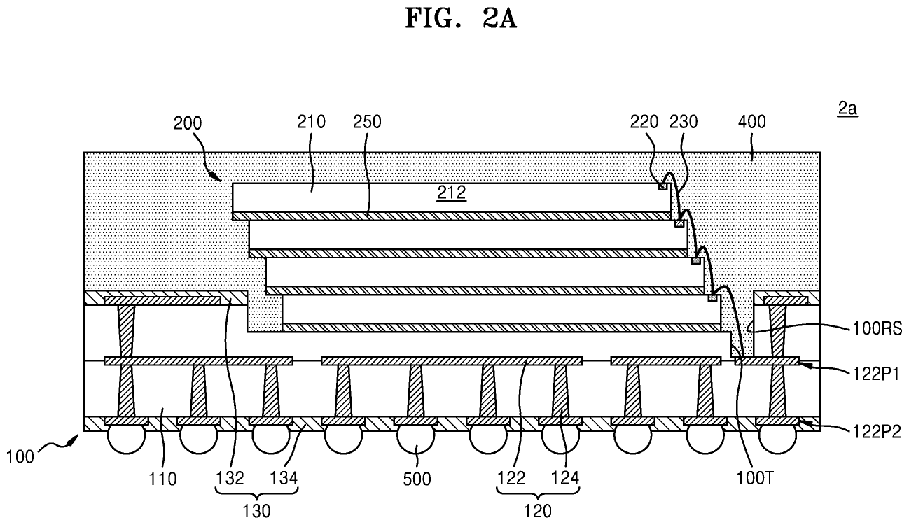

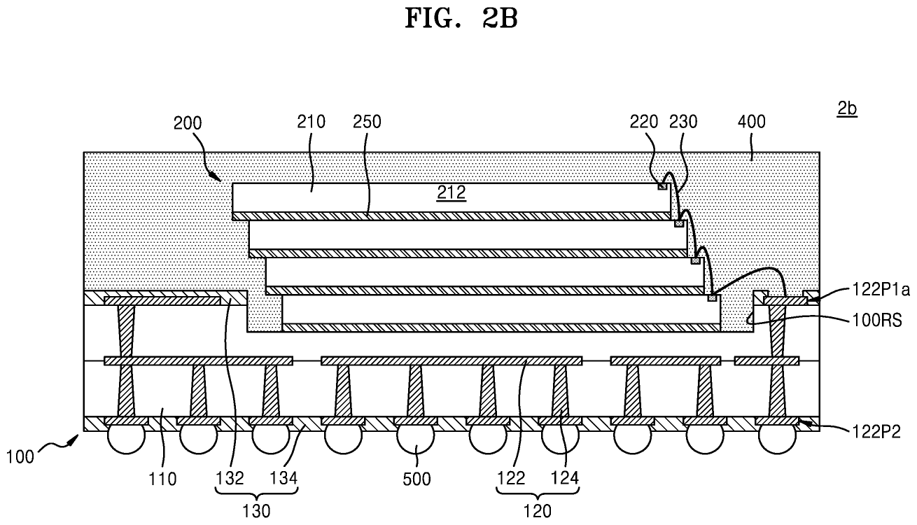

FIGS. 2A and 2B are cross-sectional views of a semiconductor package according to embodiments. Referring to FIG. 2A, a semiconductor package 2a may include a package base substrate 100 and a plurality of second semiconductor chips 200.

The package base substrate 100 may include a base insulating layer 110 and a plurality of conductive patterns 120. The plurality of conductive patterns 120 may include a plurality of substrate wiring patterns 122 and a plurality of substrate conductive vias 124. Some substrate wiring patterns 122 that are adjacent to the bottom surface of the package base substrate 100 may be referred to as a plurality of lower connection pads 122P2, and some substrate wiring patterns 122 that are adjacent to the top surface of the package base substrate 100 may be referred to as a plurality of upper connection pads 122P1. The plurality of upper connection pads 122P1 may be disposed on the top surface of a base insulating layer 110 that is directly below the uppermost base insulating layer 110.

The package base substrate 100 may include a substrate cavity 100RS which extends from the top surface of the package base substrate 100 toward the bottom surface of the package base substrate 100. The substrate cavity 100RS may pass through the top solder resist layer 132 and extend toward the inside of the package base substrate 100. In some embodiments, because the substrate cavity 100RS passes through the top solder resist layer 132 and passes through only the upper portion of the base insulating layer 110, only a portion of the base insulating layer 110 may be exposed at the bottom of the substrate cavity 100RS, and the substrate wiring pattern 122 might not be exposed thereto.

When the package base substrate 100 includes the plurality of stacked base insulating layers 110, the substrate cavity 100RS may pass through the top solder resist layer 132 and pass through only the upper portion of the uppermost base insulating layer 110. For example, the substrate cavity 100RS may pass through the top solder resist layer 132 and pass through the upper portion of the uppermost base insulating layer 110 among the plurality of base insulating layers 110, but the substrate cavity 100RS might not extend to the bottom surface of the uppermost base insulating layer 110.

The package base substrate 100 may further include a pad trench 100T which extends from the bottom of the substrate cavity 100RS toward the bottom surface of the package base substrate 100. The pad trench 100T may be in communication with the substrate cavity 100RS. For example, upper connection pads 122P1 disposed in pad trench 100T may communicate with upper connection pads 122P1 disposed in the substrate cavity 100RS.

When the package base substrate 100 includes a plurality of stacked base insulating layers 110, the substrate cavity 100RS and the pad trench 100T, which are in communication with each other, may pass through the top solder resist layer 132 and pass through at least one base insulating layer 110 at an upper side among the stacked base insulating layers 110, and substrate wiring patterns 122 may be exposed at the bottom of the pad trench 100T. At least some of the substrate wiring patterns 122 exposed at the bottom of the pad trench 100T may be a plurality of upper connection pads 122P1.

A plurality of semiconductor chips 200 may be sequentially stacked on the package base substrate 100 in a vertical direction. For example, the plurality of stacked semiconductor chips 200 may be sequentially stacked in a vertical direction from the bottom of the substrate cavity 100RS of the package base substrate 100. Each of the plurality of semiconductor chips 200 may be shifted with regular spacing intervals in a horizontal direction to form a step shape.

In some embodiments, the plurality of bonding wires 230 may be sequentially connected to each of the plurality of chip pads 220 of the uppermost semiconductor chip 200 to the plurality of chip pads 220 of the lowermost semiconductor chip 200, and may be connected to the plurality of upper connection pads 122P1.

The plurality of semiconductor chips 200 may each have the die adhesive film 250 attached to a lower surface thereof, and the die adhesive film 250 may also be attached to the lower structure. For example, the lowermost semiconductor chip 200 may be attached to the bottom of the substrate cavity 100RS of the package base substrate 100 with the die adhesive film 250, and the remaining semiconductor chips 200 may be attached to another lower semiconductor chip 200 with the die adhesive film 250 therebetween. The die adhesive film 250, which covers the bottom surface of the lowermost semiconductor chip 200, may cover the portion of the base insulating layer 110 exposed at the bottom of the substrate cavity 100RS.

The plurality of semiconductor chips 200 may be sequentially stacked on the bottom of the substrate cavity 100R in a vertical direction and be spaced apart from the inner sidewall of the substrate cavity 100RS of the package base substrate 100. Some of the plurality of semiconductor chips 200 may be located within the substrate cavity 100RS. For example, the lower portion of the stacked semiconductor chips 200 may be positioned in the substrate cavity 100RS, and the upper portion of the stacked semiconductor chips 200 may be positioned outside the substrate cavity 100RS. The lower portion of the semiconductor chips 200 may include one or more semiconductor chips 200, or may include only a portion of one semiconductor chip 200, and similarly for the upper portion of the semiconductor chips 200.

In some embodiments, the plurality of upper connection pads 122P1 may be arranged on the top surface of the base insulating layer 110 that is positioned on the bottom of the pad trench 100T. For example, the plurality of upper connection pads 122P1 may be arranged on the top surface of a base insulating layer directly below the uppermost base insulating layer 110. A plurality of bonding wires 230 may be attached between the plurality of chip pads 220 and the plurality of upper connection pads 122P1a. Some of the plurality of bonding wires 230 may be positioned in the pad trench 100T, and some of the plurality of bonding wires 230 may be positioned in the substrate cavity 100RS, and other bonding wires of the plurality of bonding wires 230 may be positioned outside the substrate cavity 100RS.

A mold layer 400 may be arranged on the package base substrate 100 and cover the top surface of the package base substrate 100 to fill the pad trench 100T and the substrate cavity 100RS, and cover the plurality of semiconductor chips 200 and the plurality of bonding wires 230.

Referring to FIG. 2B, a semiconductor package 2b may include a package base substrate 100 and a plurality of second semiconductor chips 200.

The package base substrate 100 may include a base insulating layer 110 and a plurality of conductive patterns 120. The package base substrate 100 may have a substrate cavity 100RS which extends from the top surface of the package base substrate 100 toward the bottom of the package base substrate 100. The plurality of stacked semiconductor chips 200 may be sequentially stacked in a vertical direction from the bottom of the substrate cavity 100RS of the package base substrate 100.

The plurality of conductive patterns 120 may include a plurality of substrate wiring patterns 122 and a plurality of substrate conductive vias 124. Some substrate wiring patterns 122 that are adjacent to the bottom surface of the package base substrate 100 may be referred to as a plurality of lower connection pads 122P2, and some substrate wiring patterns 122 that are adjacent to the top surface of the package base substrate 100 may be referred to as a plurality of upper connection pads 122P1a. In some embodiments, the plurality of upper connection pads 122P1a may be disposed on the top surface of the uppermost base insulating layer 110. The top solder resist layer 132 may cover the top surface of the uppermost base insulating layer 110 and expose the plurality of upper connection pads 122P1a.

A plurality of bonding wires 230 may be attached to the plurality of chip pads 220 and the plurality of upper connection pads 122P1a. For example, one end of each of the bonding wires 230 may be connected to each of the plurality of chip pads 220 of the lowermost semiconductor chip 200, and the other end of each of the bonding wires 230 may be connected to each of the plurality of upper connection pads 122P1a. In some embodiments, when the entirety of the semiconductor chip 200 or more is positioned in the substrate cavity 100RS, the plurality of upper connection pads 122P1a may be disposed at a vertical level higher than that of the plurality of chip pads 220 of the lowermost semiconductor chip 200. In some embodiments, when only the lower portion of the lowermost semiconductor chip 200 is positioned in the substrate cavity 100RS, the plurality of upper connection pads 122P1a may be disposed at a vertical level lower than that of the plurality of chip pads 220 of the lowermost semiconductor chip 200.

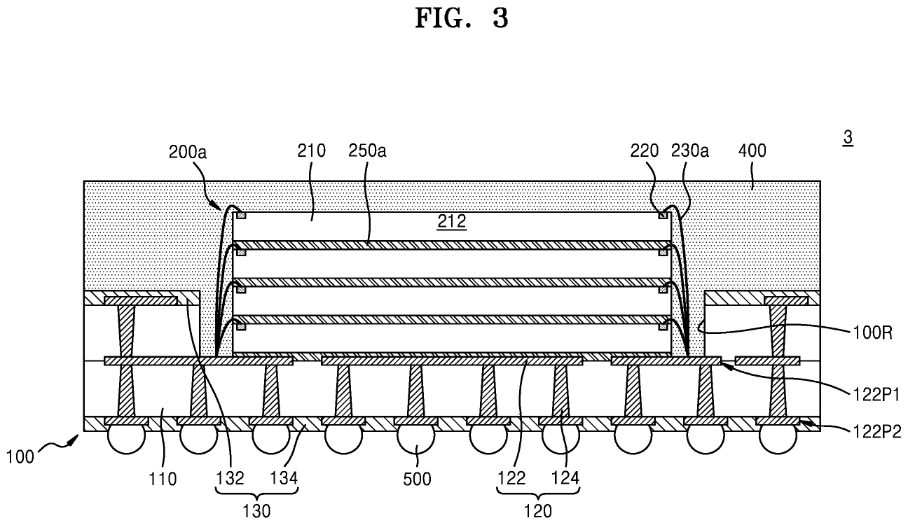

FIG. 3 is a cross-sectional view of a semiconductor package according to an embodiment.

Referring to FIG. 3, a semiconductor package 3 may include a package base substrate 100 and a plurality of second semiconductor chips 200a.

The package base substrate 100 may include a base insulating layer 110 and a plurality of conductive patterns 120. The package base substrate 100 may include a substrate cavity 100R which extends from the top surface of the package base substrate 100 toward the bottom of the package base substrate 100. The plurality of stacked semiconductor chips 200a may be sequentially stacked in a vertical direction from the bottom of the substrate cavity 100R of the package base substrate 100.

A plurality of semiconductor chips 200a may be sequentially stacked on the package base substrate 100 in a vertical direction (e.g., a direction perpendicular to a plane of the package base substrate 100, e.g., a Z direction). For example, the plurality of stacked semiconductor chips 200a may be sequentially stacked in a vertical direction from the bottom of the substrate cavity 100R of the package base substrate 100.

The plurality of semiconductor chips 200a may be stacked to overlap with each other in the vertical direction. For example, side surfaces of the plurality of semiconductor chips 200a may be aligned with one another in the vertical direction.

Each of the plurality of semiconductor chips 200a may include a semiconductor substrate 210 having an active surface and an inactive surface opposite to the active surface, a semiconductor device 212 formed on the active surface of the semiconductor substrate 210, and a plurality of chip pads 220 arranged on the active surface. The plurality of semiconductor chips 200a may be electrically connected to the package base substrate 100 through a plurality of bonding wires 230a. The plurality of bonding wires 230a may be respectively connected to the plurality of chip pads 220 of each of the plurality of semiconductor chips 200a, and the plurality of upper connection pads 122P1.

The plurality of semiconductor chips 200a may include a die adhesive film 250a attached to the lower surface of each of the semiconductor chips 200a, and the die adhesive film 250a may be attached to the lower structure. For example, the die adhesive film 250a may attach the lowermost semiconductor chip 200a to the bottom of the substrate cavity 100R. The die adhesive film 250a may cover a plurality of chip pads 220 of the semiconductor chip 200 at the lower side. Side portions of the plurality of bonding wires 230a, which are connected to the plurality of chip pads 220, may penetrate the die adhesive film 250a. For example, the plurality of bonding wires 230a may penetrate the die adhesive film 250a to connect to the plurality of chip pads 220, respectively. In some embodiments, the die adhesive film 250a may be thicker than the die adhesive film 250 of FIG. 1A.

Although it is illustrated that a semiconductor package 3 of FIG. 3 includes a plurality of semiconductor chips 200a, a plurality of die adhesive films 250a, and a plurality of bonding wires 230a instead of a plurality of semiconductor chips 200, a plurality of die adhesive films 250, and a plurality of bonding wires 230 included in the semiconductor package 1a of FIG. 1A, embodiments are not necessarily limited thereto. For example, the semiconductor package 3 may include a plurality of semiconductor chips 200a, a plurality of die adhesive films 250a, and a plurality of bonding wires 230a instead of a plurality of semiconductor chips 200, a plurality of die adhesive films 250, and a plurality of bonding wires 230 included in the semiconductor package 1b of FIG. 1B, the semiconductor package 2a of FIG. 2A, and the semiconductor package 2b of FIG. 2B.

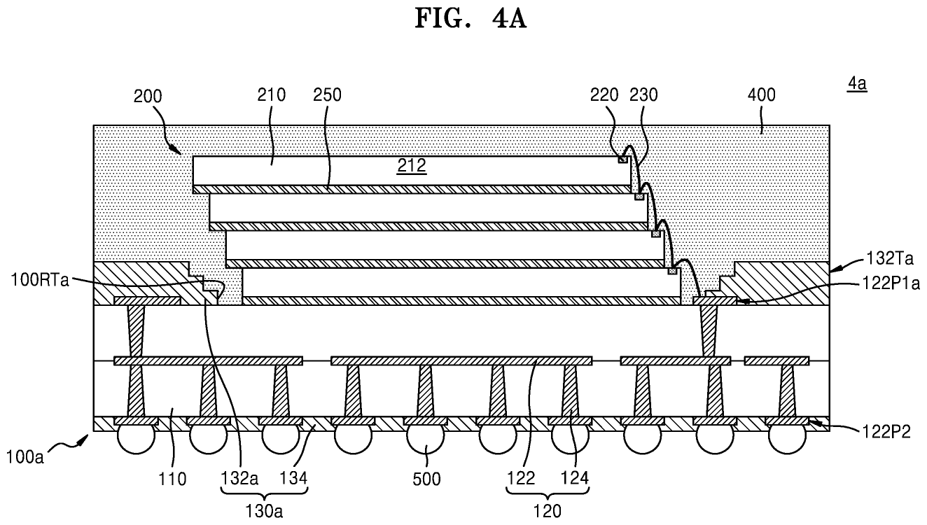

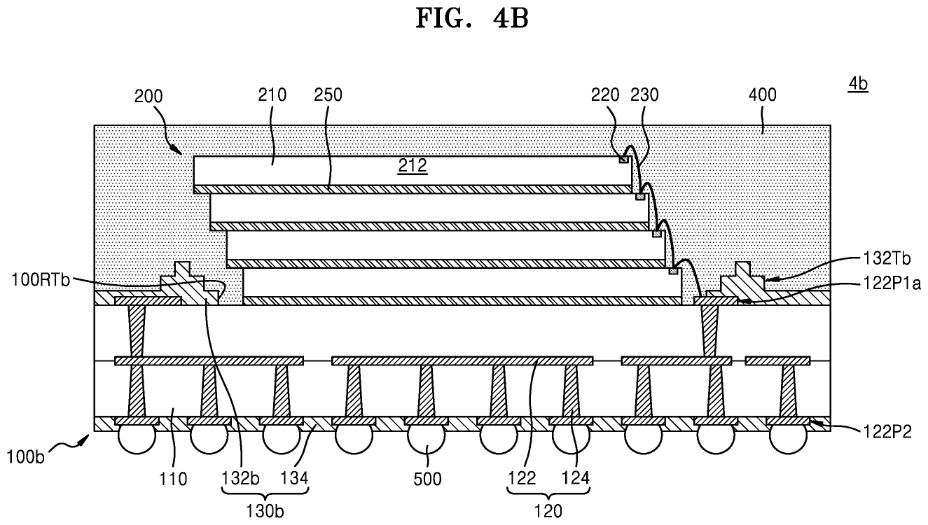

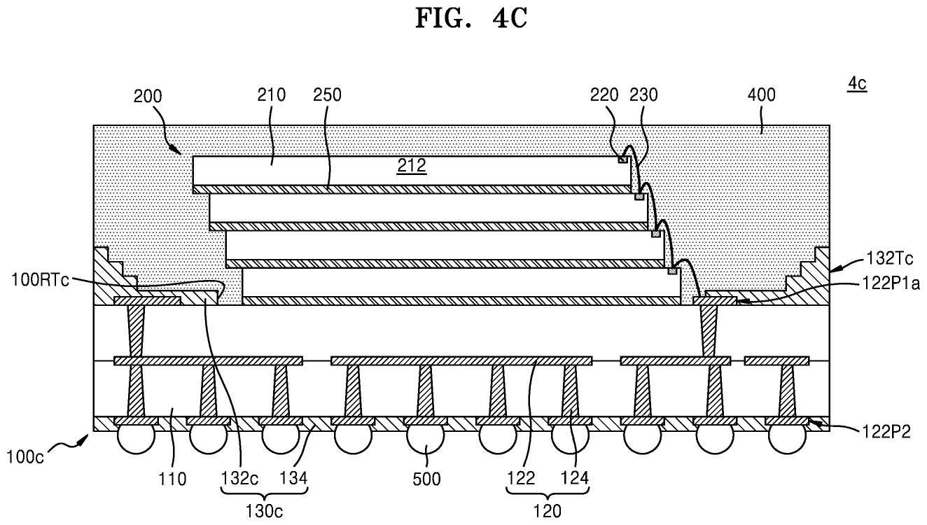

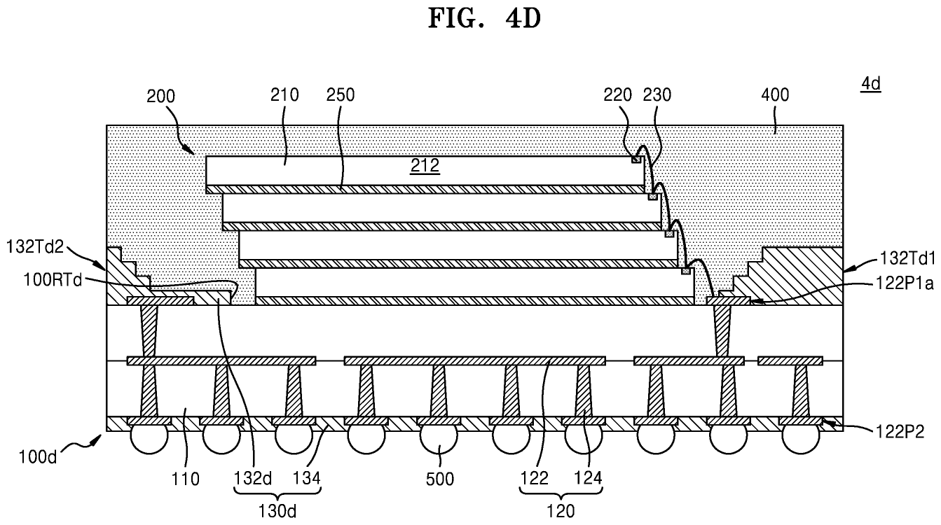

FIGS. 4A to 4D are cross-sectional views of a semiconductor package according to embodiments. Referring to FIG. 4A, a semiconductor package 4a may include a package base substrate 100a and a plurality of second semiconductor chips 200.

The package base substrate 100a may include a base insulating layer 110 and a plurality of conductive patterns 120. The plurality of conductive patterns 120 may include a plurality of substrate wiring patterns 122 and a plurality of substrate conductive vias 124. Some substrate wiring patterns 122 that are adjacent to the bottom surface of the package base substrate 100a may be referred to as a plurality of lower connection pads 122P2, and some substrate wiring patterns 122 that are adjacent to the top surface of the package base substrate 100a may be referred to as a plurality of upper connection pads 122P1a. The plurality of upper connection pads 122P1a may be disposed on the top surface of the uppermost base insulating layer 110.

The package base substrate 100a may further include a solder resist layer 130a on the top surface and the bottom surface of the base insulating layer 110. For example, when the package base substrate 100a includes a plurality of stacked base insulating layers 110, the solder resist layer 130a may be arranged on the top surface of the base insulating layer 110 and the bottom surface of the lowermost base insulating layer 110. The solder resist layer 130a may include a top solder resist layer 132a which covers the top surface of the base insulating layer 110 and exposes the plurality of upper connection pads 122P1a, and a bottom solder resist layer 134 which covers the bottom surface of the base insulating layer 110 and exposes the plurality of lower connection pads 122P2. In some embodiments, the top solder resist layer 132a may be thicker than the bottom solder resist layer 134. For example, the thickness of the thickest portion of the top solder resist layer 132a may be greater than the thickness of the thickest portion of the bottom surface solder resist layer 134.

The package base substrate 100a may include a substrate cavity 100RTa which extends from the top surface of the package base substrate 100 toward the bottom of the package base substrate 100. The substrate cavity 100RTa may pass through the top solder resist layer 132a. In some embodiments, the substrate cavity 100RTa may pass through the top solder resist layer 132a and may not pass through the base insulating layer 110. The base insulating layer 110 and the substrate wiring patterns 122 may be exposed on the bottom of the substrate cavity 100RTa. At least some of the substrate wiring patterns 122 exposed at the bottom of the substrate cavity 100RTa may be a plurality of upper connection pads 122P1a.

The lateral width of the substrate cavity 100RTa may generally increase from the lower side of the substrate cavity 100RTa to the upper side of the substrate cavity 100RTa. The shape of substrate cavity 100RTa may be formed by the top solder resist layer 132a. Accordingly, the lateral width of the top solder resist layer 132a between the side surface of the package base substrate 100a and the substrate cavity 100RTa may be reduced from the lower side of the top solder resist layer 132a to the upper side of the top solder resist layer 132a.

In some embodiments, the inner side surface of the substrate cavity 100RTa, that is, the side surface of the top solder resist layer 132a in the substrate cavity 100RTa may include a step shape rising toward the side surface of the package base substrate 100a. In some embodiments, the top solder resist layer 132a may include a stack structure of a plurality of sub solder resist layers, and each of the plurality of sub solder resist layers may form a step shape.

The top solder resist layer 132a may include a solder protrusion 132Ta on the side surface of the package base substrate 100a. The solder protrusion 132Ta may be the thickest portion of the top solder resist layer 132a. When the top solder resist layer 132a has a stack structure of a plurality of sub solder resist layers, the solder protrusion 132Ta may be a portion of the plurality of sub solder resist layers excluding the lowermost sub solder resist layer. The solder protrusion 132Ta may extend from the side surface of the package base substrate 100a to the substrate cavity 100RTa with a substantially constant thickness, and the thickness of the solder protrusion 132Ta may decrease in a step shape in a position adjacent to the substrate cavity 100RTa.

A plurality of semiconductor chips 200 may be sequentially stacked on the package base substrate 100a in a vertical direction. For example, the plurality of stacked semiconductor chips 200 may be sequentially stacked in a vertical direction from the bottom of the substrate cavity 100RTa of the package base substrate 100a. Each of the plurality of semiconductor chips 200 may be shifted with regular spacing intervals in a horizontal direction to form a step shape. The plurality of semiconductor chips 200 may be sequentially stacked on the bottom of the substrate cavity 100RTa in a vertical direction and be spaced apart from the inner sidewall of the substrate cavity 100RTa of the package base substrate 100a.

In some embodiments, a part of the upper portion of the plurality of stacked semiconductor chips 200 may not overlap with the substrate cavity 100RTa in the vertical direction. For example, a portion of the upper portion of the plurality of stacked semiconductor chips 200 may overhang the substrate cavity 100RTa in the horizontal direction, or may be disposed outside a planar area of the substrate cavity 100RTa as apparent from a plan view. For example, a portion of the uppermost semiconductor chip 200 shifted to the lowermost semiconductor chip 200 in the horizontal direction, or a portion of the upper semiconductor chips 200 may be positioned at the outer side of the substrate cavity 100Ta in a plan view. For example, a part of the upper portion of the plurality of stacked semiconductor chips 200 may extend towards the solder protrusion 132Ta to thereby overlap with the solder protrusion 132Ta in the vertical direction.

The plurality of semiconductor chips 200 may include the die adhesive film 250 attached to the lower surface of each of the semiconductor chips 200, and the die adhesive film 250 may be attached to the lower structure. For example, the lowermost semiconductor chip 200 may be attached to the bottom of the substrate cavity 100RTa of the package base substrate 100a with the die adhesive film 250 therebetween, and the remaining semiconductor chips 200 may be attached to another lower semiconductor chip 200 with the die adhesive film 250 therebetween. The die adhesive film 250, which covers the bottom surface of the lowermost semiconductor chip 200, may cover the upper portion of the base insulating layer 110 exposed at the bottom of the substrate cavity 100RTa.

A mold layer 400 may be arranged on the package base substrate 100a and cover the top surface of the package base substrate 100a to fill the substrate cavity 100RTa, and cover the plurality of semiconductor chips 200 and the plurality of bonding wires 230. A portion of the solder protrusion 132Ta may be positioned below a semiconductor chip 200 which overhangs another semiconductor chip 200 at the lower side among the plurality of semiconductor chips 200 of the semiconductor package 4a. Accordingly, the structural reliability of the plurality of semiconductor chips 200 stacked on the package base substrate 100a may be increased. For example, the solder protrusion 132Ta may provide structural support for one or more of the plurality of semiconductor chips 200.

Because the lateral width of the substrate cavity 100RTa of the semiconductor package 4a increases from its lower side to its upper side thereof, a wire bonding process for connecting a plurality of bonding wires 230 to a plurality of upper connection pads 122P1a on the bottom of the substrate cavity 100RTa may be performed more easily.

Referring to FIG. 4B, a semiconductor package 4b may include a package base substrate 100a and a plurality of second semiconductor chips 200. The package base substrate 100b may include a base insulating layer 110 and a plurality of conductive patterns 120.

The package base substrate 100b may further include a solder resist layer 130b on the top surface and the bottom surface of the base insulating layer 110. The solder resist layer 130b may include a top solder resist layer 132b which covers the top surface of the base insulating layer 110 and exposes the plurality of upper connection pads 122P1a, and a bottom solder resist layer 134 which covers the bottom surface of the base insulating layer 110 and exposes the plurality of lower connection pads 122P2. In some embodiments, the top solder resist layer 132b may be thicker than the bottom solder resist layer 134. For example, the thickness of the thickest portion of the top solder resist layer 132b may be greater than the thickness of the thickest portion of the bottom surface solder resist layer 134.

The package base substrate 100b may include a substrate cavity 100RTb which extends from the top surface of the package base substrate 100 toward the bottom of the package base substrate 100. The substrate cavity 100RTb may pass through the top solder resist layer 132b. In some embodiments, the substrate cavity 100RTb may pass through the top solder resist layer 132b and may not pass through the base insulating layer 110. The base insulating layer 110 and the substrate wiring patterns 122 may be exposed on the bottom of the substrate cavity 100RTb. At least some of the substrate wiring patterns 122 exposed at the bottom of the substrate cavity 100RTb may be a plurality of upper connection pads 122P1a.

The lateral width of the substrate cavity 100RTb may increase from its lower side to its upper side. The shape of the substrate cavity 100RTb may be formed by the top solder resist layer 132b. In some embodiments, the side surface of the top solder resist layer 132b may have a rising step shape. In some embodiments, the top solder resist layer 132b may include a stack structure formed by a plurality of sub solder resist layers, and each of the plurality of sub solder resist layers may form a step shape.

The top solder resist layer 132b may include a solder protrusion 132Tb around the substrate cavity 100RTb. The solder protrusion 132Tb may be the thickest portion of the top solder resist layer 132b. When the top solder resist layer 132b has a stack structure of a plurality of sub solder resist layers, the solder protrusion 132Tb may be a portion of the plurality of sub solder resist layers excluding the lowermost sub solder resist layer. The thickness of the solder protrusion 132Tb may decrease in a step shape in a position adjacent to the substrate cavity 100TRb rather than the side surface of the package base substrate 100b.

A plurality of semiconductor chips 200 may be sequentially stacked on the package base substrate 100b in a vertical direction. For example, the plurality of stacked semiconductor chips 200 may be sequentially stacked in a vertical direction from the bottom of the substrate cavity 100RTb of the package base substrate 100b.

At least a portion of the solder protrusion 132Tb may be positioned below a semiconductor chip 200 which overhangs another semiconductor chip 200 at the lower side among the plurality of semiconductor chips 200 of the semiconductor package 4b. Accordingly, the structural reliability of the plurality of semiconductor chips 200 stacked on the package base substrate 100b may be increased. For example, the solder protrusion 132Tb may provide structural support for one or more of the plurality of semiconductor chips 200.

Because the lateral width of the substrate cavity 100RTb of the semiconductor package 4b increases from its lower side to its upper side, a wire bonding process for connecting a plurality of bonding wires 230 to a plurality of upper connection pads 122P1a on the bottom of the substrate cavity 100RTb may be performed easily.

Because the semiconductor package 4b includes a solder protrusion 132Tb adjacent to the substrate cavity 100RTb, the coefficient of thermal expansion (CTE) difference between the outer side and the inner side of the semiconductor package 4c may be reduced in the horizontal direction, and thus, warpage occurrence in the semiconductor package 4b may be minimized.

Referring to FIG. 4C, a semiconductor package 4c may include a package base substrate 100c and a plurality of second semiconductor chips 200. The package base substrate 100c may include a base insulating layer 110 and a plurality of conductive patterns 120.

The package base substrate 100c may further include a solder resist layer 130c on the top surface and the bottom surface of the base insulating layer 110. The solder resist layer 130c may include a top solder resist layer 132c which covers the top surface of the base insulating layer 110 and exposes the plurality of upper connection pads 122P1a, and a bottom solder resist layer 134 which covers the bottom surface of the base insulating layer 110 and exposes the plurality of lower connection pads 122P2. In some embodiments, the top solder resist layer 132c may be thicker than the bottom solder resist layer 134. For example, the thickness of the thickest portion of the top solder resist layer 132c may be greater than the thickness of the thickest portion of the bottom surface solder resist layer 134.

The package base substrate 100c may include a substrate cavity 100RTc which extends from the top surface of the package base substrate 100 toward the bottom of the package base substrate 100. The substrate cavity 100RTc may pass through the top solder resist layer 132c. In some embodiments, the substrate cavity 100RTc may pass through the top solder resist layer 132c and may not pass through the base insulating layer 110. The base insulating layer 110 and the substrate wiring patterns 122 may be exposed on the bottom of the substrate cavity 100RTc. At least some of the substrate wiring patterns 122 exposed at the bottom of the substrate cavity 100RTc may be a plurality of upper connection pads 122P1a.

The lateral width of the substrate cavity 100RTc may increase from its lower side to its upper side. The shape of the substrate cavity 100RTc may be formed by the top solder resist layer 132c. In some embodiments, in the inner side surface of the substrate cavity 100RTc, the side surface of the top solder resist layer 132c may have a step shape rising toward the side surface of the package base substrate 100c. In some embodiments, the top solder resist layer 132c may include a stack structure of a plurality of sub solder resist layers, and each of the plurality of sub solder resist layers may form a step shape.

The top solder resist layer 132c may include a solder protrusion 132Tc on the side surface of the package base substrate 100c. The solder protrusion 132Tc may be the thickest portion of the top solder resist layer 132c. When the top solder resist layer 132c has a stack structure of a plurality of sub solder resist layers, the solder protrusion 132Tc may be a portion of the plurality of sub solder resist layers excluding the lowermost sub solder resist layer. The thickness of the solder protrusion 132Tc may decrease in a step shape in a position adjacent to the side surface of the package base substrate 100b.

A plurality of semiconductor chips 200 may be sequentially stacked on the package base substrate 100c in a vertical direction. For example, the plurality of stacked semiconductor chips 200 may be sequentially stacked in a vertical direction from the bottom of the substrate cavity 100RTc of the package base substrate 100c.

Because the lateral width of the substrate cavity 100RTc of the semiconductor package 4c increases from its lower side to its upper side, a wire bonding process for connecting a plurality of bonding wires 230 to a plurality of upper connection pads 122P1a on the bottom of the substrate cavity 100RTc may be performed easily.

Because the semiconductor package 4c includes a solder protrusion 132Tc adjacent to the side surface of the package base substrate 100c, the CTE difference between the outer side and the inner side of the semiconductor package 4c may be reduced in the horizontal direction, and warpage occurrence in the semiconductor package 4c may be minimized. Accordingly, the semiconductor package 4c may have increased resilience during manufacture and during operation.

Referring to FIG. 4D, a semiconductor package 4d may include a package base substrate 100d and a plurality of second semiconductor chips 200. The package base substrate 100d may include a base insulating layer 110 and a plurality of conductive patterns 120.

The package base substrate 100d may further include a solder resist layer 130d on the top surface and the bottom surface of the base insulating layer 110. The solder resist layer 130d may include a top solder resist layer 132d which covers the top surface of the base insulating layer 110 and exposes the plurality of upper connection pads 122P1a, and a bottom solder resist layer 134 which covers the bottom surface of the base insulating layer 110 and exposes the plurality of lower connection pads 122P2. In some embodiments, the top solder resist layer 132d may be thicker than the bottom solder resist layer 134. For example, the thickness of the thickest portion of the top solder resist layer 132d may be greater than the thickness of the thickest portion of the bottom surface solder resist layer 134.

The package base substrate 100d may include a substrate cavity 100RTd which extends from the top surface of the package base substrate 100 toward the bottom of the package base substrate 100. The substrate cavity 100RTd may pass through the top solder resist layer 132d. In some embodiments, the substrate cavity 100RTd may pass through the top solder resist layer 132d and may not pass through the base insulating layer 110. The base insulating layer 110 and the substrate wiring patterns 122 may be exposed on the bottom of the substrate cavity 100RTd. At least some of the substrate wiring patterns 122 exposed at the bottom of the substrate cavity 100RTd may be a plurality of upper connection pads 122P1a.

The lateral width of the substrate cavity 100RTd may increase from its lower side to its upper side. The shape of the substrate cavity 100RTd may be formed by the top solder resist layer 132d. In some embodiments, in the inner side surface of the substrate cavity 100RTd, the side surface of the top solder resist layer 132d may have a step shape rising toward the side surface of the package base substrate 100d. In some embodiments, the top solder resist layer 132d may include a stack structure of a plurality of sub solder resist layers, and each of the plurality of sub solder resist layers may form a step shape.

The top solder resist layer 132d may include a first solder protrusion 132Td1 and a second solder protrusion 132Td2 separated from each other at each of both sides of the substrate cavity 100RTd at the side surface of the package base substrate 100d. The first solder protrusion 132Td1 and the second solder protrusion 132Td2 may be the thickest portions of the top solder resist layer 132d. For example, the first solder protrusion 132Td1 and the second solder protrusion 132Td2 may be disposed on both sides of the substrate cavity 100RTd and shifted in a horizontal direction to allow the plurality of semiconductor chips 200 to have a step shape. When the top solder resist layer 132d has a stack structure of a plurality of sub solder resist layers, each of the first solder protrusion 132Td1 and the second solder protrusion 132Td2 may be a portion of the plurality of sub solder resist layers excluding the lowermost sub solder resist layer. The thickness of each of the first solder protrusion 132Td1 and the second solder protrusion 132Td2 may increase in a step shape rising toward the side surface of the package base substrate 100d.

The shape of the first solder protrusion 132Td1 and the shape of the second solder protrusion 132Td2 are asymmetric across the center of the package base substrate 100d in the horizontal direction. For example, the thickness of the first solder protrusion 132Td1 may increase in a position relatively adjacent to the side surface of the package base substrate 100d, and the thickness of the second solder protrusion 132Td2 may increase in a position relatively adjacent to the substrate cavity 100RTd. In one example, the second solder protrusion 132Td2 includes a lower portion that extends in a horizontal direction for a greater distance than a corresponding lower portion of the first solder protrusion 132Td1.

A plurality of semiconductor chips 200 may be sequentially stacked on the package base substrate 100d in a vertical direction. For example, the plurality of stacked semiconductor chips 200 may be sequentially stacked in a vertical direction from the bottom of the substrate cavity 100RTd of the package base substrate 100d.

The semiconductor package 4d may include a first solder protrusion 132Td1 and a second solder protrusion 132Td2 asymmetric to each other, disposed in a portion of the semiconductor package 4d which needs an adjustment of the CTE. Accordingly, because the CTE difference of portions, which may have a CTE difference in the semiconductor package 4d, may be reduced, the warpage occurrence in the semiconductor package 4d may be minimized.

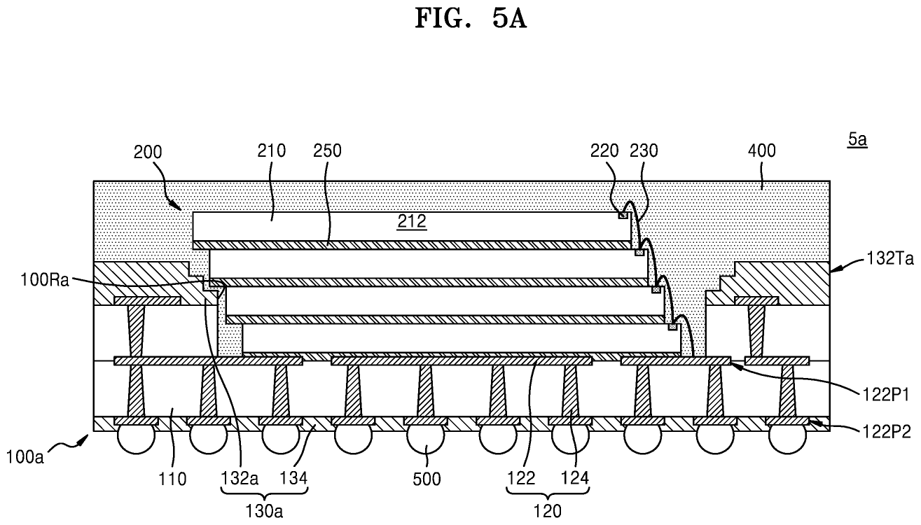

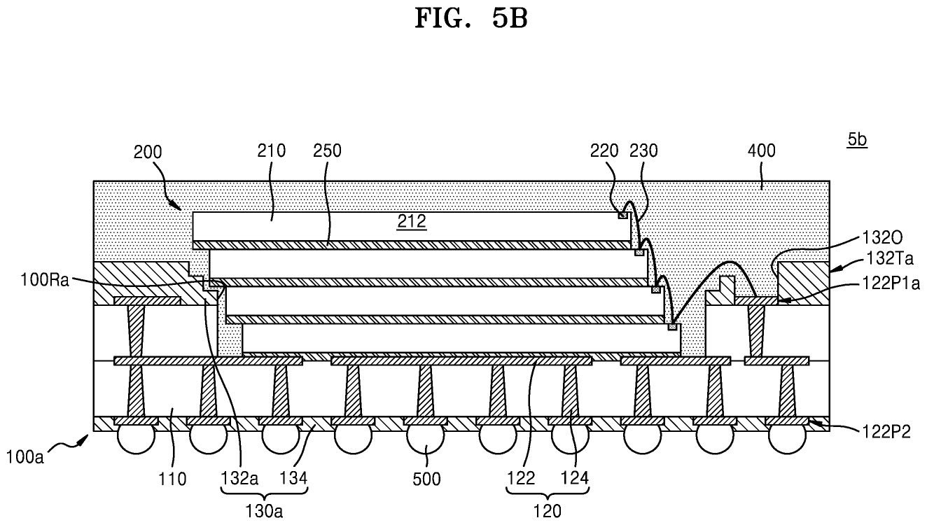

FIGS. 5A and 5B are cross-sectional views of a semiconductor package according to embodiments.

Referring to FIG. 5A, a semiconductor package 5a may include a package base substrate 100a and a plurality of second semiconductor chips 200. The package base substrate 100a may include a base insulating layer 110 and a plurality of conductive patterns 120. The plurality of conductive patterns 120 may include a plurality of substrate wiring patterns 122 and a plurality of substrate conductive vias 124. Some substrate wiring patterns 122 that are adjacent to the bottom surface of the package base substrate 100a may be referred to as a plurality of lower connection pads 122P2, and some substrate wiring patterns 122 that are adjacent to the top surface of the package base substrate 100a may be referred to as a plurality of upper connection pads 122P1.

The package base substrate 100a may further include a solder resist layer 130a on the top surface and the bottom surface of the base insulating layer 110. For example, when the package base substrate 100a includes a plurality of stacked base insulating layers 110, the solder resist layer 130a may be arranged on the top surface of the uppermost base insulating layer 110 and the bottom surface of the lowermost base insulating layer 110. The solder resist layer 130a may include a top solder resist layer 132a which covers the top surface of the base insulating layer 110, and a bottom solder resist layer 134 which covers the bottom surface of the base insulating layer 110 and exposes the plurality of lower connection pads 122P2.

The package base substrate 100a may include a substrate cavity 100Ra which extends from the top surface of the package base substrate 100 toward the bottom of the package base substrate 100. The substrate cavity 100Ra may pass through the top solder resist layer 132a and extend toward the inside of the package base substrate 100a. In some embodiments, when the package base substrate 100a includes a plurality of stacked base insulating layers 110, the substrate cavity 100Ra may pass through the top solder resist layer 132a and pass through at least one base insulating layer 110 at an upper side among the stacked base insulating layers 110, and expose substrate wiring patterns 122 at the bottom of the substrate cavity 100Ra. At least some of the substrate wiring patterns 122 exposed at the bottom of the substrate cavity 100Ra may be a plurality of upper connection pads 122P1.

The width of the substrate cavity 100Ra may increase from the bottom surface of the top solder resist layer 132a to the top surface thereof. Accordingly, the lateral width of the top solder resist layer 132a between the side surface of the package base substrate 100a and the substrate cavity 100Ra may be reduced from its lower side to its upper side.

The top solder resist layer 132a may include a solder protrusion 132Ta on the side surface of the package base substrate 100a. The solder protrusion 132Ta may be the thickest portion of the top solder resist layer 132a. When the top solder resist layer 132a includes a stack structure of a plurality of sub solder resist layers, the solder protrusion 132Ta may be a portion of the plurality of sub solder resist layers excluding the lowermost sub solder resist layer. The solder protrusion 132Ta may extend from the side surface of the package base substrate 100a to the substrate cavity 100RTa with a substantially constant thickness, and the thickness of the solder protrusion 132Ta may decrease in a step shape in a position adjacent to the substrate cavity 100RTa.

A plurality of semiconductor chips 200 may be sequentially stacked on the package base substrate 100a in a vertical direction. For example, the plurality of stacked semiconductor chips 200 may be sequentially stacked in a vertical direction from the bottom of the substrate cavity 100Ra of the package base substrate 100a. Each of the plurality of semiconductor chips 200 may be shifted with regular spacing intervals in a horizontal direction to form a step shape. The plurality of semiconductor chips 200 may be sequentially stacked on the bottom of the substrate cavity 100Ra in a vertical direction and be spaced apart from the inner sidewall of the substrate cavity 100Ra of the package base substrate 100a.

A mold layer 400, may be arranged on the package base substrate 100a and cover the top surface of the package base substrate 100a to fill the substrate cavity 100Ra, and cover the plurality of semiconductor chips 200 and the plurality of bonding wires 230.

Referring to FIG. 5B, a semiconductor package 5b may include a package base substrate 100a and a plurality of second semiconductor chips 200. The package base substrate 100a may include a base insulating layer 110 and a plurality of conductive patterns 120. The plurality of conductive patterns 120 may include a plurality of substrate wiring patterns 122 and a plurality of substrate conductive vias 124. Some substrate wiring patterns 122 that are adjacent to the bottom surface of the package base substrate 100a may be referred to as a plurality of lower connection pads 122P2, and some substrate wiring patterns 122 that are adjacent to the top surface of the package base substrate 100a may be referred to as a plurality of upper connection pads 122P1a.

The package base substrate 100a may further include a solder resist layer 130a on the top surface and the bottom surface of the base insulating layer 110. The solder resist layer 130a may include a top solder resist layer 132a which covers the top surface of the base insulating layer 110 and exposes the plurality of upper connection pads 122P1a, and a bottom solder resist layer 134 which covers the bottom surface of the base insulating layer 110 and exposes the plurality of lower connection pads 122P2. In some embodiments, the top solder resist layer 132a may include a solder opening 132O which passes through the top solder resist layer 132a and exposes the plurality of upper connection pads 122P1a on the bottom thereof. The package base substrate 100a may include a substrate cavity 100Ra which extends from the top surface of the package base substrate 100 toward the bottom of the package base substrate 100.

A plurality of bonding wires 230 may be attached to the plurality of chip pads 220 and the plurality of upper connection pads 122P1a. Some of the plurality of bonding wires 230 may be located in the solder opening 132O, and the remaining ones may be located outside the solder opening 132O.

A mold layer 400 may be arranged on the package base substrate 100a and cover the top surface of the package base substrate 100a to fill the substrate cavity 100Ra and the solder opening 132O, and cover the plurality of semiconductor chips 200 and the plurality of bonding wires 230.

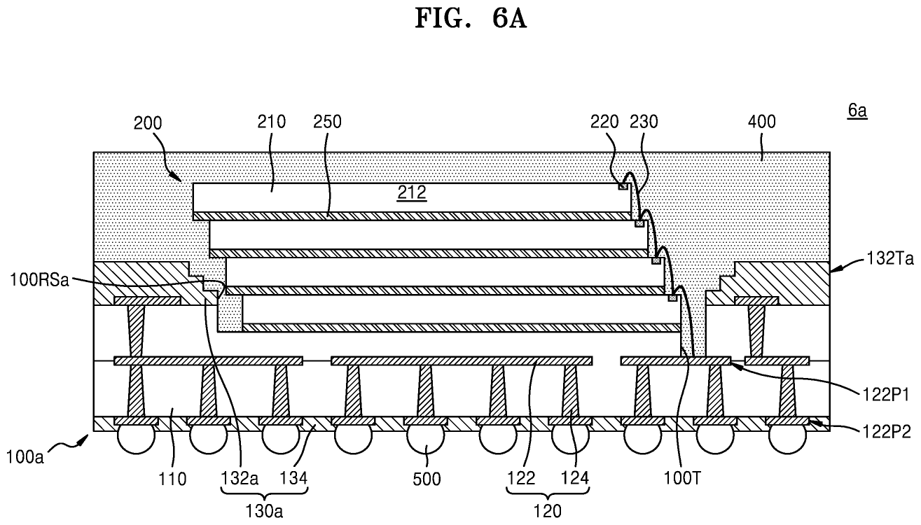

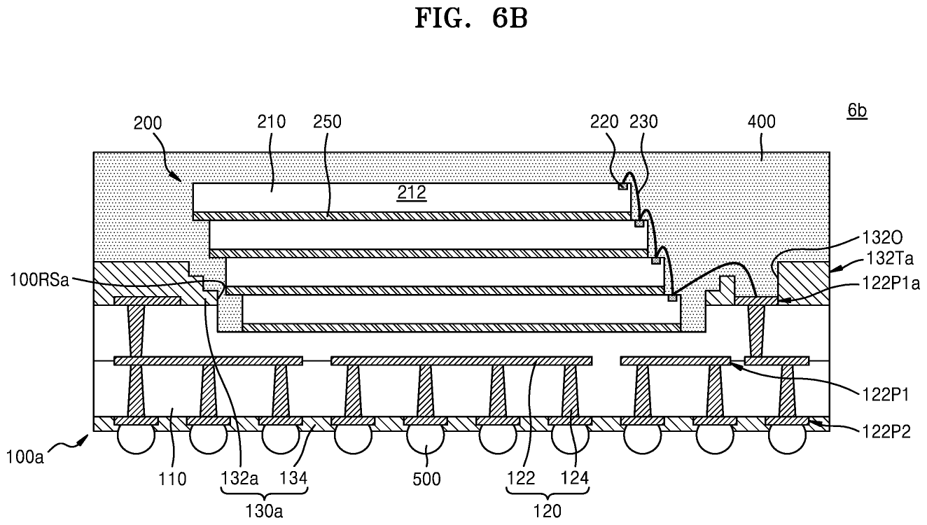

FIGS. 6A and 6B are cross-sectional views of a semiconductor package according to embodiments. Referring to FIG. 6A, a semiconductor package 6a may include a package base substrate 100a and a plurality of second semiconductor chips 200. The package base substrate 100a may include a base insulating layer 110 and a plurality of conductive patterns 120. The plurality of conductive patterns 120 may include a plurality of substrate wiring patterns 122 and a plurality of substrate conductive vias 124. Some substrate wiring patterns 122 that are adjacent to the bottom surface of the package base substrate 100a may be referred to as a plurality of lower connection pads 122P2, and some substrate wiring patterns 122 that are adjacent to the top surface of the package base substrate 100a may be referred to as a plurality of upper connection pads 122P1.

The package base substrate 100a may further include a solder resist layer 130a on the top surface and the bottom surface of the base insulating layer 110. For example, when the package base substrate 100a includes a plurality of stacked base insulating layers 110, the solder resist layer 130a may be arranged on the top surface of the base insulating layer 110 and the bottom surface of the lowermost base insulating layer 110. The solder resist layer 130a may include a top solder resist layer 132a which covers the top surface of the base insulating layer 110, and a bottom solder resist layer 134 which covers the bottom surface of the base insulating layer 110 and exposes the plurality of lower connection pads 122P2.

The package base substrate 100a may include a substrate cavity 100RSa which extends from the top surface of the package base substrate 100 toward the bottom of the package base substrate 100. The substrate cavity 100RSa may pass through the top solder resist layer 132a and extend toward the inside of the package base substrate 100a. In some embodiments, because the substrate cavity 100RSa passes through the top solder resist layer 132a and passes through only the upper portion of the base insulating layer 110a, only the portion of the base insulating layer 110 may be exposed at the bottom of the substrate cavity 100RSa, and the substrate wiring pattern 122 may not be exposed thereto.

The width of the substrate cavity 100RSa may increase from the bottom surface of the top solder resist layer 132a to the top surface thereof. Accordingly, the lateral width of the top solder resist layer 132a between the side surface of the package base substrate 100a and the substrate cavity 100RSa may be reduced from its lower side to its upper side. The top solder resist layer 132a may include a solder protrusion 132Ta on the side surface of the package base substrate 100a. The solder protrusion 132Ta may be the thickest portion of the top solder resist layer 132a.

The package base substrate 100a may further include a pad trench 100T which extends from the bottom of the substrate cavity 100RSa toward the bottom surface of the package base substrate 100a. The pad trench 100T may be in communication with the substrate cavity 100RSa. For example, some of a plurality of upper connection pads 122P1 may be disposed in the pad trench 100T, and electrically connected to components disposed within the substrate cavity 100RSa. When the package base substrate 100 includes a plurality of stacked base insulating layers 110, the substrate cavity 100RSa and the pad trench 100T, which are in communication with each other, may pass through the top solder resist layer 132a and pass through at least one base insulating layer 110 at an upper side among the stacked base insulating layers 110, and substrate wiring patterns 122 may be exposed at the bottom of the pad trench 100T. At least some of the substrate wiring patterns 122 exposed at the bottom of the pad trench 100T may be the plurality of upper connection pads 122P1.

A mold layer 400 may be arranged on the package base substrate 100a and cover the top surface of the package base substrate 100a to fill the substrate cavity 100RSa, and cover the plurality of semiconductor chips 200 and the plurality of bonding wires 230

Referring to FIG. 6B, a semiconductor package 6b may include a package base substrate 100a and a plurality of second semiconductor chips 200. The package base substrate 100a may include a base insulating layer 110 and a plurality of conductive patterns 120. The plurality of conductive patterns 120 may include a plurality of substrate wiring patterns 122 and a plurality of substrate conductive vias 124. Some substrate wiring patterns 122 that are adjacent to the bottom surface of the package base substrate 100a may be referred to as a plurality of lower connection pads 122P2, and some substrate wiring patterns 122 that are adjacent to the top surface of the package base substrate 100a may be referred to as a plurality of upper connection pads 122P1a.

The package base substrate 100a may further include a solder resist layer 130a on the top surface and the bottom surface of the base insulating layer 110. The solder resist layer 130a may include a top solder resist layer 132a which covers the top surface of the base insulating layer 110 and exposes the plurality of upper connection pads 122P1a, and a bottom solder resist layer 134 which covers the bottom surface of the base insulating layer 110 and exposes the plurality of lower connection pads 122P2. In some embodiments, the top solder resist layer 132a may include a solder opening 132O which passes through the top solder resist layer 132a and exposes the plurality of upper connection pads 122P1a on the bottom thereof.

The package base substrate 100a may include a substrate cavity 100RSa which extends from the top surface of the package base substrate 100 toward the bottom of the package base substrate 100. The substrate cavity 100RSa may pass through the top solder resist layer 132a and extend toward the inside of the package base substrate 100a. In some embodiments, because the substrate cavity 100RSa passes through the top solder resist layer 132a and passes through only the upper portion of the base insulating layer 110a, only the portion of the base insulating layer 110 may be exposed at the bottom of the substrate cavity 100RSa, and the substrate wiring pattern 122 may not be exposed thereto.

A plurality of bonding wires 230 may be attached to the plurality of chip pads 220 and the plurality of upper connection pads 122P1a. Some of the plurality of bonding wires 230 may be located in the solder opening 132O, and the remaining ones may be located outside the solder opening 132O.

A mold layer 400 may be arranged on the package base substrate 100a and cover the top surface of the package base substrate 100a to fill the substrate cavity 100Ra and the solder opening 132O, and cover the plurality of semiconductor chips 200 and the plurality of bonding wires 230.

Although it is illustrated that each of the semiconductor package 5a of FIG. 5A, the semiconductor package 5b of FIG. 5B, the semiconductor package 6a of FIG. 6A and the semiconductor package of FIG. 6B includes substantially the same top solder resist layer 132a as that of FIG. 4A, embodiments are not necessarily limited thereto. For example, each of the semiconductor package 5a of FIG. 5A, the semiconductor package 5b of FIG. 5B, the semiconductor package 6a of FIG. 6A, and the semiconductor package 6B of FIG. 6B may include the top solder resist layer 132b of FIG. 4B, the top solder resist layer 132c of FIG. 4C, or the top solder resist layer 132d of FIG. 4D.

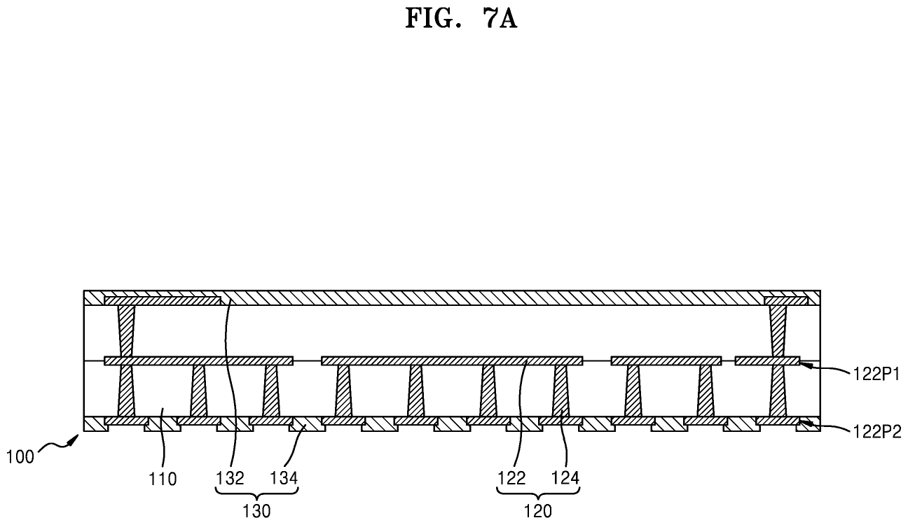

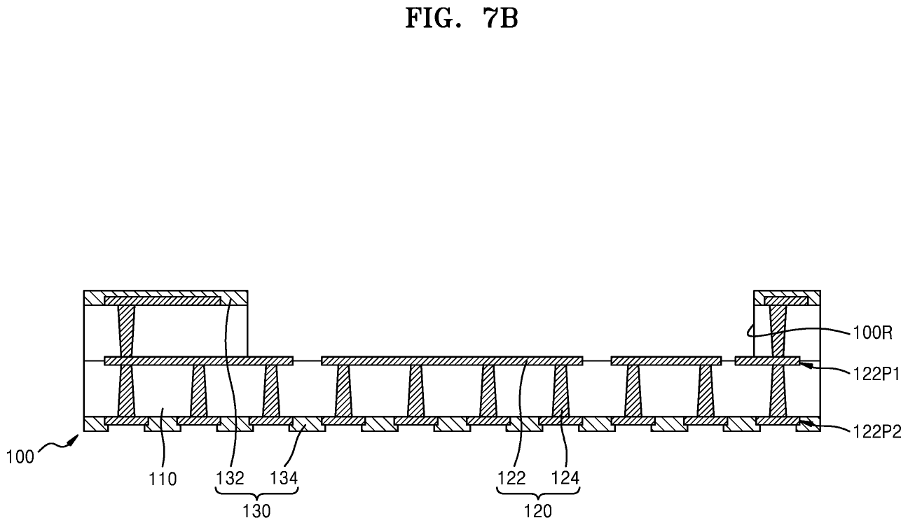

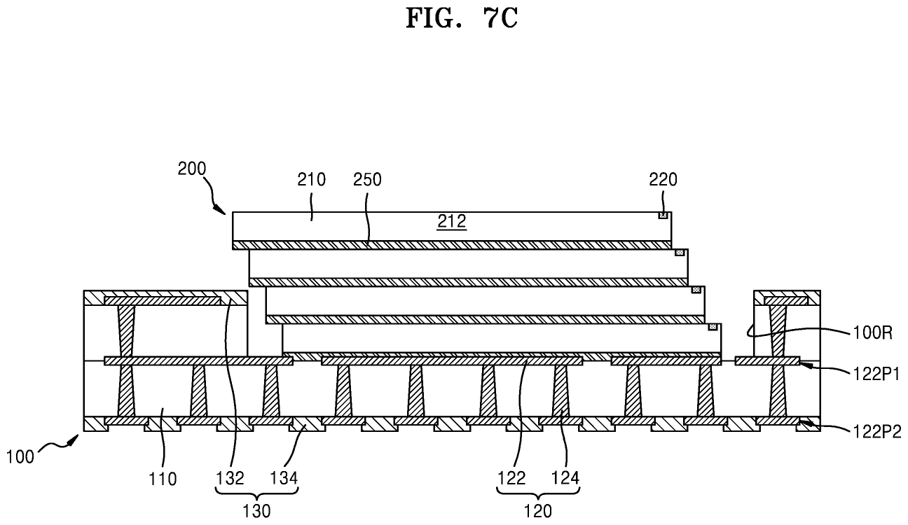

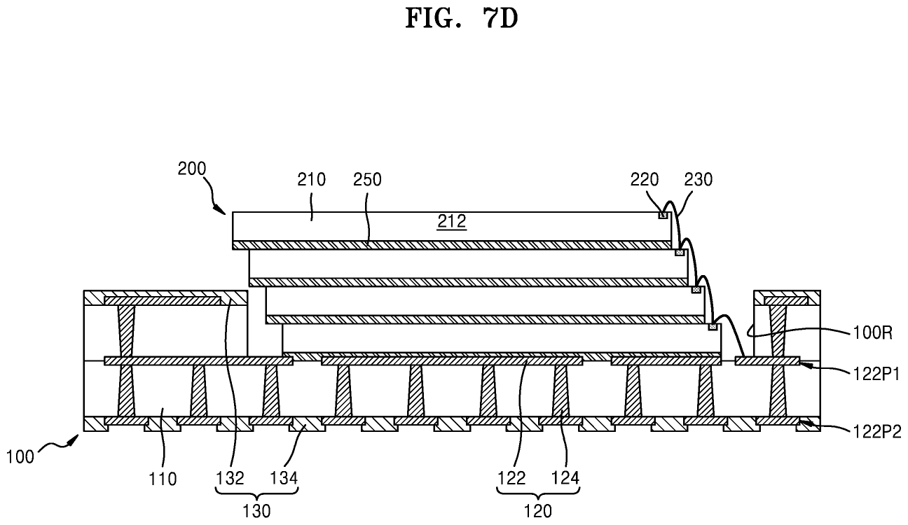

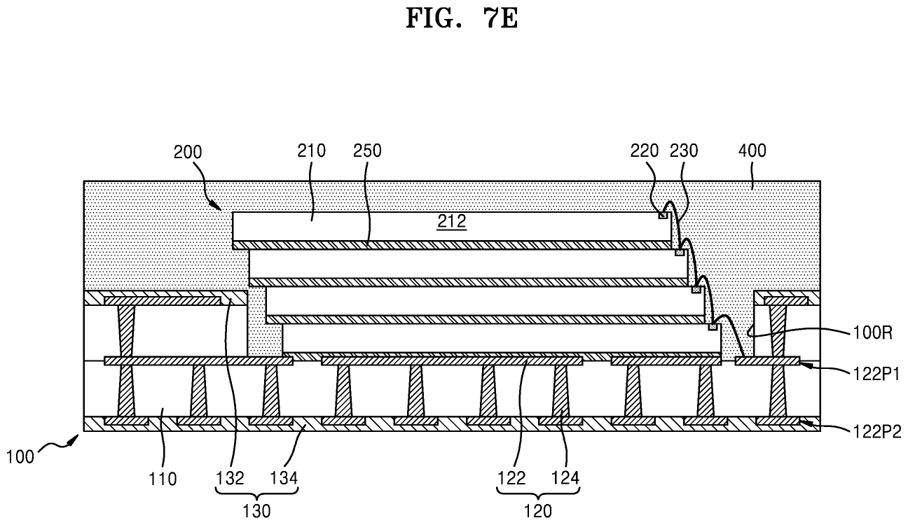

FIGS. 7A to 7E are cross-sectional views of a method of manufacturing a semiconductor package, according to embodiments. Referring to FIG. 7A, a package base substrate 100 may be prepared. The package base substrate 100 may include a base insulating layer 110 and a plurality of conductive patterns 120. The plurality of conductive patterns 120 may include a plurality of substrate wiring patterns 122 and a plurality of substrate conductive vias 124. The package base substrate 100 may further include a solder resist layer 130 disposed on the top surface and the bottom surface of the base insulating layer 110. The solder resist layer 130 may include a top solder resist layer 132 which covers the top surface of the base insulating layer 110, and a bottom solder resist layer 134 which covers the bottom surface of the base insulating layer 110 and exposes the plurality of lower connection pads 122P2.

Referring to FIG. 7B, a substrate cavity 100R extending into the package base substrate 100 from the top surface thereof is formed. The substrate cavity 100R may be formed by removing a portion of the top solder resist layer 132 and a portion of the base insulating layer 110. In some embodiments, when the package base substrate 100 includes a plurality of stacked base insulating layers 110, the substrate cavity 100R may be formed by removing a portion of the top solder resist layer 132 and a portion of at least one base insulating layer 110 at an upper side among the plurality of stacked base insulating layers 110. The substrate cavity 100R may pass through the top solder resist layer 132 and at least one base insulating layer 110 at the upper side among the plurality of stacked base insulating layers 110. In some embodiments, the substrate cavity 100R may be formed to allow the substrate wiring patterns 122 to be exposed at the bottom.

Referring to FIG. 7C, a plurality of semiconductor chips 200 are sequentially stacked on the bottom surface of the substrate cavity 100R of the package base substrate 100 in a vertical direction. For example, the plurality of semiconductor chips 200 may be sequentially stacked on the bottom of the substrate cavity 100R of the package base substrate 100 in a vertical direction. Each of the plurality of semiconductor chips 200 may be shifted with regular spacing intervals in a horizontal direction to form a step shape.

In some embodiments, the plurality of semiconductor chips 200 may be stacked on the package base substrate 100 such that a portion of the upper portion of the plurality of stacked semiconductor chips 200 does not overlap with the substrate cavity 100R in the vertical direction. For example, at least one semiconductor chip 200 at the upper side among the plurality of stacked semiconductor chips 200 may be stacked on another semiconductor chip 200 at the lower side to allow a portion of the at least one semiconductor chip 200 to overhang the substrate cavity 100R in the horizontal direction. In other words, a portion of one or more semiconductor chips among upper semiconductor chips of the plurality of semiconductor chips may extend beyond the planar area of the substrate cavity 100R in the horizontal direction.

Referring to FIG. 7D, a plurality of bonding wires 230 for connecting a plurality of chip pads 220 including a plurality of semiconductor chips 200 to a plurality of upper connection pads 122P1 are formed. For example, the plurality of bonding wires 230 may be sequentially connected to each of the plurality of chip pads 220 of the uppermost semiconductor chip 200 to the plurality of chip pads 220 of the lowermost semiconductor chip 200 and may then be connected to the plurality of upper connection pads 122P1. In some embodiments, some of the plurality of bonding wires 230 may be formed to be positioned within the substrate cavity 100R.

Referring to FIG. 7E, a mold layer 400, which covers the top surface of the package base substrate 100 to fill the substrate cavity 100R, and covers the plurality of semiconductor chips 200 and the plurality of bonding wires 230, is formed on the package base substrate 100.

Thereafter, as shown in FIG. 1A, a semiconductor package 1a is formed by attaching a plurality of external connection terminals 500 to a plurality of lower connection pads 122P2.

Semiconductor packages 1b, 2a, 2b, 3, 4a, 4b, 4c, 4d, 5a, 5b, 6a, and 6b of FIGS. 1B to 6B may also be formed by a similar process with reference to FIGS. 7A to 7E.

A semiconductor package according to the present disclosure includes a plurality of semiconductor chips, or a “stack” of semiconductor chips, disposed within a substrate cavity. The cavity may be formed by removing one or more base insulating layers disposed on a package substrate of the semiconductor package, or by removing a portion of one base insulating layer. A lower portion of the stack of semiconductor chips may be disposed within the cavity, thereby decreasing a height of the semiconductor package, and increasing its compactness. An upper portion of the stack of semiconductor chips may be disposed outside of the substrate cavity. Since the entirety of the stack is not disposed outside of the cavity, the upper semiconductor chips of the stack may be better supported by a solder resist layer surrounding lateral sides of the chip, thereby increasing the reliability of the semiconductor package.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package base substrate including a substrate cavity formed therein, the substrate cavity extending from a top surface of the package base substrate downwardly toward a bottom surface of the package base substrate, the package base substrate further including a plurality of base insulating layers, a plurality of substrate wiring patterns extending along at least one of a top surface and a bottom surface of each of the plurality of base insulating layers, a plurality of substrate conductive vias passing through at least one of the plurality of base insulating layers and connected to the plurality of substrate wiring patterns, and a top solder resist layer at least partially covering a top surface of an uppermost base insulating layer among the plurality of base insulating layers and a bottom solder resist layer at least partially covering a bottom surface of a lowermost base insulating layer among the plurality of base insulating layers;
a plurality of semiconductor chips disposed at a bottom of the substrate cavity, wherein the plurality of semiconductor chips are stacked in a direction that is perpendicular to a plane of the package substrate and protrude upwards above a top surface of the package base substrate; and
a plurality of bonding wires electrically connecting the plurality of semiconductor chips to the package base substrate,
wherein a portion of one or more of the plurality of semiconductor chips extends beyond the substrate cavity in a direction that is parallel to the plane of the package base substrate.

2. The semiconductor package of claim 1, further comprising a plurality of lower connection pads disposed adjacent to a bottom surface of the package base substrate, and a plurality of upper connection pads disposed adjacent to the top surface of the package base substrate, wherein one or more of the plurality of upper connection pads are connected to the plurality of bonding wires.

3. The semiconductor package of claim 2, wherein the substrate cavity penetrates through the top solder resist layer and extends into the plurality of base insulating layers.

4. The semiconductor package of claim 3, wherein the package base substrate further includes a pad trench disposed within the substrate cavity and extending downwardly toward a bottom surface of the package base substrate from the bottom of the substrate cavity, and
wherein the plurality of upper connection pads are positioned on a bottom of the pad trench.

5. The semiconductor package of claim 3, wherein the substrate cavity penetrates through the top solder resist layer and through at least one upper base insulating layer among the plurality of base insulating layers.

6. The semiconductor package of claim 3, wherein the plurality of upper connection pads are disposed on a bottom of the substrate cavity.

7. The semiconductor package of claim 3, wherein the plurality of upper connection pads are disposed on a top surface of the uppermost base insulating layer among the plurality of base insulating layers.

8. The semiconductor package of claim 7, wherein the plurality of semiconductor chips each include a plurality of chip pads connected to the plurality of bonding wires, and
wherein the plurality of chip pads of a lowermost semiconductor chip among the plurality of semiconductor chips are disposed at a level closer to the package base substrate than a level at which the plurality of upper connection pads are disposed.

9. The semiconductor package of claim 1, wherein each the plurality of semiconductor chips are offset from one another in a direction in a direction that is parallel to a plane of the package base substrate to collectively form a step shape.

10. The semiconductor package of claim 1, wherein at least a portion of the plurality of bonding wires is positioned within the substrate cavity.

11. A semiconductor package comprising:
a package base substrate, including:
a plurality of base insulating layers;
a plurality of substrate wiring patterns extending along top and bottom surfaces of each the plurality of base insulating layers;
a plurality of substrate conductive vias passing through at least one of the plurality of base insulating layers and connected to the plurality of substrate wiring patterns;
a top solder resist layer at least partially covering a top surface of an uppermost base insulating layer among the plurality of base insulating layers;
a bottom solder resist layer at least partially covering a bottom surface of a lowermost base insulating layer among the plurality of base insulating layers; and
a substrate cavity formed within the plurality of base insulating layers and passing through the top solder resist layer;
a plurality of semiconductor chips stacked on a bottom of the substrate cavity, wherein a lower portion of the plurality of semiconductor chips is disposed within the substrate cavity and wherein an upper portion of the plurality of semiconductor chips is disposed outside the substrate cavity; and
a plurality of bonding wires for connecting the plurality of semiconductor chips to the package base substrate.

12. The semiconductor package of claim 11, wherein the substrate cavity passes through the top solder resist layer and passes through at least one upper base insulating layer among the plurality of base insulating layers.

13. The semiconductor package of claim 12, wherein the plurality of substrate wiring patterns include a plurality of upper connection pads connected to the plurality of bonding wires, and
wherein the plurality of upper connection pads are disposed on a bottom of the substrate cavity.

14. The semiconductor package of claim 12, wherein the plurality of semiconductor chips include a plurality of chip pads connected to one end of the plurality of bonding wires,
wherein the plurality of substrate wiring patterns include a plurality of upper connection pads connected to the other end of the plurality of bonding wires,
wherein the plurality of upper connection pads are positioned on a top surface of the uppermost base insulating layer among the plurality of base insulating layers, and
wherein the plurality of upper connection pads are disposed at a level further from the package base substrate than an upper surface of the lowermost semiconductor chip among the plurality of semiconductor chips.

15. The semiconductor package of claim 11, wherein the substrate cavity passes through the top solder resist layer and passes through an upper portion of the uppermost base insulating layer among the plurality of base insulating layers, without extending to a bottom surface of the uppermost base insulating layer.

16. The semiconductor package of claim 15, wherein the plurality of substrate wiring patterns include a plurality of upper connection pads connected to the plurality of bonding wires,
wherein the package base substrate further includes a pad trench in communication with the substrate cavity and extending toward a bottom of the package base substrate from the bottom of the substrate cavity, and passing through at least one upper base insulating layer among the plurality of base insulating layers, and
wherein the plurality of upper connection pads are positioned on a bottom of the pad trench.

17. The semiconductor package of claim 11, wherein a portion of one or more of the plurality of semiconductor chips extends beyond the substrate cavity in a direction that is parallel to a plane of the package base substrate.

18. A semiconductor package comprising:
a package base substrate including a plurality of base insulating layers, a plurality of substrate wiring patterns extending along at least one of a top surface and a bottom surface of each of the plurality of base insulating layers, a plurality of substrate conductive vias passing through at least one of the plurality of base insulating layers and connected to the plurality of substrate wiring patterns, a top solder resist layer at least partially covering a top surface of an uppermost base insulating layer among the plurality of base insulating layers, a bottom solder resist layer at least partially covering a bottom surface of a lowermost base insulating layer among the plurality of base insulating layers, and a substrate cavity formed within the top solder resist layer and extending downwardly from a top surface of the package base substrate toward an inside of the package base substrate;
a plurality of semiconductor chips stacked on a bottom of the substrate cavity in a direction perpendicular to a plane of the package base substrate, and protruding upwards over a top surface of the package base substrate;
a plurality of bonding wires connecting the plurality of semiconductor chips to the package base substrate; and
a mold layer covering the top surface of the package base substrate and filling the substrate cavity, wherein the mold layer covers the plurality of semiconductor chips and the plurality of bonding wires,
wherein the substrate cavity is formed by a solder protrusion of the top solder resist layer, wherein a portion of the top solder resist layer including the solder protrusion has the greatest thickness within the top solder resist layer, and wherein a thickness of the thickest portion of the top solder resist layer is greater than a thickness of the thickest portion of the bottom solder resist layer.

19. The semiconductor package of claim 18, wherein at least one side surface of the solder protrusion has a step shape.

20. The semiconductor package of claim 18, wherein the solder protrusion includes a first solder protrusion and a second solder protrusion separated from each other, and
wherein a shape of the first solder protrusion and a shape of the second solder protrusion are asymmetric in a direction that is parallel to a plane of the package base substrate across a center of the package base substrate.
